(19) United States
(12) Patent Application Publication
(10) Pub. No.: US 2025/0160169 A1
(43) Pub. Date: May 15, 2025

(54) DISPLAY PANEL

(71) Applicant: Samsung Display Co., LTD., Yongin-si (KR)

(72) Inventors: DASOM YANG, Yongin-si (KR); SEUNG-YEON CHO, Yongin-si (KR)

(21) Appl. No.: 18/815,680

(22) Filed: Aug. 26, 2024

(30) Foreign Application Priority Data
Nov. 15, 2023 (KR) 10-2023-0158233

(51) Int. Cl. H10K 59/80; G09G 3/3233; H10K 59/131

(52) U.S. Cl. CPC H10K 59/80523; H10K 59/131; G09G 3/3233; G09G 2300/0413; G09G 2300/0819; G09G 2300/0842; G09G 2300/0861; G09G 2330/00; G09G 2354/00

(57) ABSTRACT

A display panel includes: a display area comprising a first area having a first light transmittance, and a second area having a second light transmittance higher than the first light transmittance; a plurality of first pixels, each of which is configured to provide the first area with light and comprises a first cathode; a plurality of second pixels configured to provide the second area with light, and including a second cathode overlapping the first cathode in a plan view and electrically insulated from the first cathode; a first power part connected to the first cathode and configured to supply a first power voltage to the first cathode; a second power part connected to the second cathode and configured to supply a second power voltage different from the first power voltage to the second cathode; and a cathode insulation layer between the first cathode and the second cathode.

### CROSS-REFERENCE TO RELATED APPLICATIONS

The present application claims priority to and the benefit of Korean Patent Application No. 10-2023-0158233, filed on Nov. 15, 2023, in the Korean Intellectual Property Office, the entire disclosure of which is incorporated herein by reference.

### BACKGROUND

Aspects of some embodiments of the present disclosure relate to a display panel.

A display device may be a device including various electronic components such as a display panel that displays images, an input sensing unit that detects an external input, and an electronic module. The electronic components may be electrically connected to each other through signal lines variously arranged. The display panel includes a light emitting element that generates light.

The input sensing unit may include detection electrodes for detecting an external input. The electronic module may include a camera, an infrared ray sensor, a proximity sensor, or the like. The electronic module may be located below the display panel.

The above information disclosed in this Background section is only for enhancement of understanding of the background and therefore the information discussed in this Background section does not necessarily constitute prior art.

### SUMMARY

Aspects of some embodiments of the present disclosure relate to a display panel, and for example, to a display panel with relatively improved overall display quality of a display area.

Aspects of some embodiments of the present disclosure include a display panel that may be capable of relatively improving display quality of a display area on which an electronic module is located.

According to some embodiments of the present disclosure, a display panel includes: a display area, which includes a first area having a first light transmittance, and a second area adjacent to the first area and having a second light transmittance higher than the first light transmittance, a plurality of first pixels, each of which provides the first area with light and includes a first cathode, a plurality of second pixels, each of which provides the second area with light, and includes a second cathode overlapping the first cathode on a plane (or in a plan view) and electrically insulated from the first cathode, a first power part connected to the first cathode to supply a first power voltage to the first cathode, a second power part connected to the second cathode to supply a second power voltage different from the first power voltage to the second cathode, and a cathode insulation layer between the first cathode and the second cathode.

According to some embodiments, a hole passing through the first cathode and the cathode insulation layer may be defined in the second area, and the second cathode may pass through the first cathode and the cathode insulation layer through the hole to be connected to the second power part.

According to some embodiments, the hole may be in an edge of the first area.

According to some embodiments, the display panel may further include a dummy pixel provided in the second area, and the hole may overlap the dummy pixel on a plane (or in a plan view).

According to some embodiments, the hole may be provided in plurality, and the holes may be arranged along an edge of the second area.

According to some embodiments, the second cathode may be spaced apart from the first area on a plane (or in a plan view).

According to some embodiments, the second cathode may overlap the first area and the second area on a plane (or in a plan view).

According to some embodiments, the second power voltage may have a lower voltage level than the first power voltage.

According to some embodiments, the first power part may include a first power line in a peripheral area adjacent to the display area, and a first power auxiliary line branched from the first power line, and extending from the peripheral area to the first area to be electrically connected to the first cathode. According to some embodiments, the second power part may include a second power line in the peripheral area, and a second power auxiliary line branched from the second power line, and extending from the peripheral area to the second area to be electrically connected to the second cathode.

According to some embodiments, the hole and the second power auxiliary line may overlap each other on a plane (or in a plan view).

According to some embodiments, the second power auxiliary line may extend along the first area so as to have a minimum distance between the second area and the peripheral area.

According to some embodiments, the display panel may further include a base layer on which the first power line and the second power line are located, and a first insulation layer on the base layer. According to some embodiments, the first cathode may be on the first insulation layer.

According to some embodiments, the display panel may further include a first anode on the base layer and overlapping the first area, a second anode on the base layer and overlapping the second area, and an organic layer on the base layer and comprising an emission layer. The second power auxiliary line may be on the same layer as the second anode.

According to some embodiments of the present disclosure, a display panel includes a display area, which includes a first area having a first light transmittance, and a second area adjacent to the first area and having a second light transmittance higher than the first light transmittance, a first anode which is in the first area, a second anode which is in the second area, an organic layer which includes an emission layer on the first anode and the second anode, a first cathode which is on the first area, a second cathode which is in the second area, on a different layer from the first cathode, and electrically insulated from the first cathode, a first power part which is connected to the first cathode, and a second power part which is connected to the second cathode. According to some embodiments, a hole defined in the second area and passing through the first cathode may be defined, and the second cathode may pass through the first cathode through the hole to be connected to the second power part.

According to some embodiments, the display panel may further include a cathode insulation layer between the first cathode and the second cathode. The hole further may pass through the cathode insulation layer, and the second cathode may pass through the first cathode and the cathode insulation layer through the hole to be connected to the second power part.

According to some embodiments, the display panel may further include a peripheral area adjacent to the display area. According to some embodiments, the first power part may include a first power line in the peripheral area, and a first power auxiliary line branched from the first power line, and extending from the peripheral area to the first area to be electrically connected to the first cathode. According to some embodiments, the second power part may include a second power line in the peripheral area, and a second power auxiliary line branched from the second power line, and extending from the peripheral area to the second area to be electrically connected to the second cathode.

According to some embodiments, the hole and the second power auxiliary line may overlap each other on a plane (or in a plan view).

According to some embodiments, the display panel may further include a base layer on which the first power line and the second power line are located, and a first insulation layer on the base layer. According to some embodiments, the first cathode may be on the first insulation layer.

According to some embodiments, the first anode and the second anode may be on the base layer, and the second power auxiliary line may be on the same layer as the second anode.

According to some embodiments, the first power part may supply a first power voltage to the first cathode, and the second power part may supply a second power voltage having a lower voltage level than the first power voltage to the second cathode.

### BRIEF DESCRIPTION OF THE FIGURES

The accompanying drawings are included to provide a further understanding of embodiments according to some embodiments of the present disclosure, and are incorporated in and constitute a part of this specification. The drawings illustrate aspects of some embodiments of the present disclosure and, together with the description, serve to explain characteristics of some embodiments of the present disclosure. In the drawings:

FIG. 1A is a perspective view of a display device according to some embodiments of the present disclosure;

FIG. 1B is an exploded perspective view of a display device according to some embodiments of the present disclosure;

FIG. 2 is a block diagram of a display device according to some embodiments of the present disclosure;

FIG. 3A is a plan view of a display panel according to some embodiments of the present disclosure;

FIG. 3B is a plan view of a display panel according to some embodiments of the present disclosure;

FIG. 4A is an enlarged plan view illustrating a portion of a first display area according to some embodiments of the present disclosure;

FIG. 4B is an enlarged plan view illustrating a portion of a second display area according to some embodiments of the present disclosure;

FIG. 4C is an enlarged plan view illustrating a portion of a second display area according to some embodiments of the present disclosure;

FIG. 5A is an equivalent circuit diagram of a first red pixel according to some embodiments of the present disclosure;

FIG. 5B is an equivalent circuit diagram of a second red pixel according to some embodiments of the present disclosure;

FIG. 6 is a plan view of a display panel according to some embodiments of the present disclosure;

FIGS. 7A to 7D are cross-sectional views of a display panel according to some embodiments of the present disclosure;

FIG. 8 is a plan view of a display panel according to some embodiments of the present disclosure;

FIG. 9A is an enlarged plan view of a portion of a display panel according to some embodiments of the present disclosure;

FIGS. 9B and 9C are enlarged cross-sectional views of a portion of a display panel according to some embodiments of the present disclosure;

FIGS. 10A and 10B are enlarged plan views of a portion of a display panel according to some embodiments of the present disclosure; and

FIGS. 11A and 11B are plan views of a display panel according to some embodiments of the present disclosure.

### DETAILED DESCRIPTION

In this specification, it will be understood that when an element (or region, layer, section, etc.) is referred to as being “on”, “connected to” or “coupled to” another element, it can be located directly on, connected or coupled to the other element or a third intervening elements may be located between the elements.

Like reference numbers or symbols refer to like elements throughout. In addition, in the drawings, the thickness, the ratio, and the dimension of elements are exaggerated for effective description of the technical contents. The term “and/or” includes one or more combinations which may be defined by relevant elements.

It will be understood that, although the terms first, second, etc. may be used herein to describe various elements, these elements should not be limited by these terms. These terms are only used to distinguish one element from another element. For example, a first element could be termed a second element without departing from the teachings of the present invention, and similarly, a second element could be termed a first element. As used herein, the singular forms are intended to include the plural forms as well, unless the context clearly indicates otherwise.

In addition, the terms, such as “below”, “beneath”, “on” and “above”, are used for explaining the relation of elements shown in the drawings. The terms are relative concept and are explained based on the direction shown in the drawing.

It will be further understood that the terms such as “includes” or “has”, when used herein, specify the presence of stated features, numerals, steps, operations, elements, parts, or the combination thereof, but do not preclude the presence or addition of one or more other features, numerals, steps, operations, elements, parts, or the combination thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, a display panel and a method for manufacturing the same according to some embodiments of the present disclosure will be described in more detail with reference to the accompanying drawings.

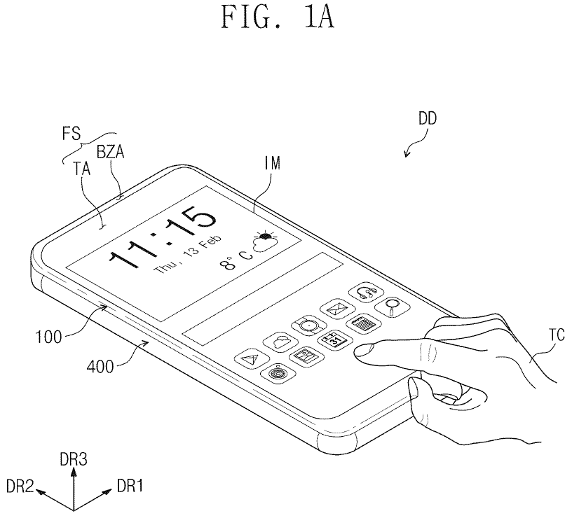

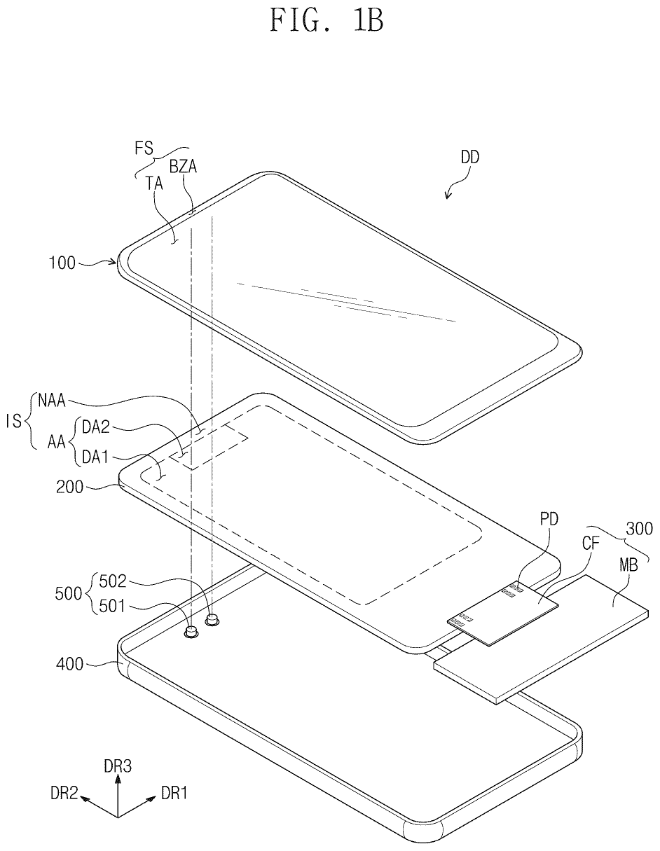

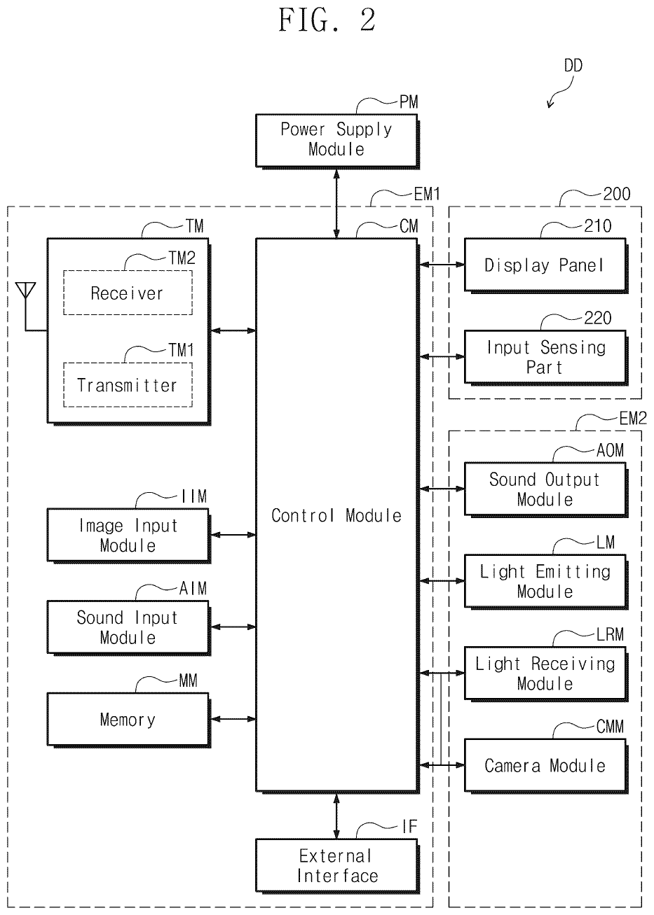

FIG. 1A is a perspective view of a display device according to some embodiments of the present disclosure. FIG. 1B is an exploded perspective view of a display device according to some embodiments of the present disclosure. FIG. 2 is a block diagram of a display device according to some embodiments of the present disclosure.

Referring to FIGS. 1A to 2, a display device DD may be a device that is activated in response to an electrical signal. The display device DD may include various embodiments. For examples, the display device DD may include a tablet computer, a notebook computer, a computer, a smart television, or the like. In FIGS. 1A-2, a smartphone is illustrated as an example of the display device DD, but embodiments according to the present disclosure are not limited thereto.

The display device DD may display an image IM on a display surface FS, which is parallel to each of a first direction DR1 and a second direction DR2, in a third direction DR3. The display surface FS on which the image IM is displayed may correspond to a front surface of the display device DD, and may correspond to a front surface FS of a window 100. Hereinafter, the same reference symbol is used for the display surface and the front surface of the display device DD, and the front surface FS of the window 100. The image IM may include not only a dynamic image (e.g., video images) but also a still image (e.g., a static image). FIG. 1A illustrates a clock window and application icons as an example of the image IM.

In FIG. 1A, a front surface (or top surface) and a rear surface (or bottom surface) of each member is defined based on a direction in which the image IM is displayed. The front surface and the rear surface may oppose each other in the third direction DR3, and a normal direction to each of the front surface and the rear surface may be parallel to the third direction DR3. Meanwhile, directions indicated by the first to third directions DR1, DR2 and DR3 are relative concepts and may be changed to other directions.

The display device DD may include the window 100, a display module 200, a driving circuit part 300, a housing 400, and electronic modules 500. According to some embodiments, the window 100 and the housing 400 may be coupled to each other to provide an outer appearance of the display device DD.

The window 100 may include an optically transparent insulation material. For examples, the window 100 may include glass or plastic. The window 100 may have a single-layer or multilayer structure. For example, the window 100 may include a plurality of plastic films coupled to each other through an adhesive, or include a glass substrate and a plastic film coupled to each other through an adhesive.

The window 100 may be divided into a transmission area TA and a bezel area BZA on a plane or in a plan view. The phrase “on a plane” or “in a plan view” herein may mean a state when viewed in the third direction DR3. In addition, a “thickness direction” may mean the third direction DR3.

The transmission area TA may be an optically transparent area. The bezel area BZA may be an area having a relatively low light transmittance when compared to the transmission area TA. The bezel area BZA may define a shape of the transmission area TA. The bezel area BZA may be adjacent to the transmission area TA and surround the transmission area TA.

The bezel area BZA may have a color (e.g., a set or predetermined color). The bezel area BZA may cover a peripheral area NAA of the display module 200 to block the peripheral area NAA from being visible from the outside. However, this is illustrated as one example, and the bezel area BZA may be omitted in the window 100 according to some embodiments of the present disclosure.

The display module 200 may be located below the window 100. The term “below” used herein may mean a direction opposite to a direction in which the display module 200 provides an image. The display module 200 may display an image IM and detect a user's input TC. The display module 200 has a front surface including an active area AA and a peripheral area NAA. The active area AA may be an area that is activated in response to an electrical signal.

According to some embodiments, the active area AA may be an area on which the image IM is displayed, and also an area through which the user's input TC is detected. The transmission area TA at least overlaps the active area AA. For example, the transmission area TA overlaps a front surface or at least a portion of the active area AA. Accordingly, the user may see the image IM through the transmission area TA or provide the user's input TC.

The peripheral area NAA may be an area that is covered by the bezel area BZA. The peripheral area NAA is adjacent to (e.g., in a periphery or outside a footprint of) the active area AA. The peripheral area NAA may surround the active area AA. A driving circuit, a driving line, or the like for driving the active area AA may be located in the peripheral area NAA.

According to some embodiments, the display module 200 is assembled in a flat state in which the active area AA and the peripheral area NAA face the window 100. However, this is illustrated as an example, and a portion of the peripheral area NAA may be bent. Here, as the portion of the peripheral area NAA faces a rear surface of the display device DD, a surface area of the bezel area BZA in the front surface of the display device DD may be relatively reduced. Alternatively, the display module 200 may be assembled in a state in which a portion of the active area AA is also bent. Alternatively, Alternatively, the peripheral area NAA may be omitted in display module 200 according to some embodiments of the present disclosure.

The active area AA of the display module 200 may include a plurality of display areas. The plurality of display areas may have different light transmittances. According to some embodiments, the active area AA of the display module 200 includes a first display area DA1 and a second display area DA2. The second display area DA2 may have a higher light transmittance than the first display area DA1.

The driving circuit part 300 may be electrically connected to the display module 200. The driving circuit part 300 may include a main circuit board MB and a flexible film CF.

The flexible film CF is electrically connected to the display module 200. The flexible film CF may be connected to pads PD of the display module 200 located in the peripheral area NAA. The flexible film CF provides the display module 200 with an electrical signal for driving the display module 200. The electrical signal may be generated from the flexible film CF, or generated from the main circuit board MB. The main circuit board may include various driving circuits for driving the display module 200, a connector for supplying power, or the like.

The electronic modules 500 may include a first electronic module 501 and a second electronic module 502. The first and second electronic modules 501 and 502 may overlap the second display area DA2 on a plane (or in a plan view). The first and second electronic modules 501 and 502 may be located below the display module 200.

The first and second electronic modules 501 and 502 may receive an external input transmitted through the second display area DA2, or may output a signal through the second display area DA2. That is, as the second display area DA2 has a higher light transmittance than the first display area DA1, and the electronic modules 500 may easily transmit and/or receive a signal through the second display area DA2.

The housing 400 is coupled to the window 100. The housing 400 is coupled to the window 100 to provide an inner space (e.g., within the housing 400, and between a bottom surface of the housing 400 and the window 100). The display module 200 and the electronic modules 500 may be accommodated in the inner space. The housing 400 may include a material having relatively high rigidity. For

examples, the housing 400 may include glass, plastic, or metal, or include a plurality of frames and/or plates made of a combination thereof. The housing 400 may stably protect components of the display device DD accommodated in the inner space from damage caused by an external impact.

Referring to FIG. 2, the display device DD may include a display module 200, a power supply module PM, a first electronic module EM1, and a second electronic module EM2. The display module 200, the power supply module PM, the first electronic module EM1, and the second electronic module EM2 may be electrically connected to each other.

The display module 200 may include a display panel 210 and an input sensing part 220.

The display panel 210 may be a component that generates the image IM. The image IM generated by the display panel 210 is displayed on the front surface, and is externally visible to the user through the transmission area TA toward the direction DR3.

The input sensing part 220 may detect the user's input TC applied from the outside. For example, the input sensing part 220 may detect the user's input TC provided to the window 100. The user's input may include various types of external inputs such as part of the user's body (e.g., a user's finger), light, heat, pen (or stylus), or pressure. In FIG. 2, the user's input TC is illustrated as the user's hand applied to the front surface FS. However, this is illustrated as an example, and the user's input TC may be provided in various types as described above. The display device DD may also detect the user's input TC applied to a side surface or a rear surface of the display device DD according to a structure of the display device DD, but embodiments according to the present disclosure are not limited to any one embodiment.

The power supply module PM supplies power required for the overall operation of the display device DD. The power supply module PM may include a typical battery module.

The first electronic module EM1 and the second electronic module EM2 may include various functional modules for operating the display device DD.

The first electronic module EM1 may be mounted directly on a motherboard electrically connected to the display module 200, or mounted on a separate board to be electrically connected to the motherboard through a connector or the like.

The first electronic module EM1 may include a control module CM, a wireless communication module TM, an image input module IIM, a sound input module AIM, a memory MM, and an external interface IF. Some of the modules may also be electrically connected to the motherboard through a flexible circuit board without being mounted on the motherboard.

The control module CM controls the overall operation of the display device DD. The control module CM may be a microprocessor. For example, the control module CM activates or inactivates the display module 200. The control module CM may control other modules such as the image input module IIM or the sound input module AIM on the basis of a touch signal received from the display module 200.

The wireless communication module TM may transmit/receive a wireless signal to/from another terminal using a Bluetooth or WiFi channel. The wireless communication module may transmit/receive an audio signal using a general communication channel. The wireless communication 5 module TM may include a transmitter TM1 that modulates and transmits a signal to be transmitted, and a receiver TM2 that demodulates a signal to be received.

The image input module IIM processes an image signal to convert the image signal to image data displayable on the display module 200. The sound input module AIM receives an external sound signal through a microphone in a recording mode, an audio recognition mode, etc., and converts the external audio signal to electrical audio data.

The external interface IF may serve as an interface connected to an external charger, a wired/wireless data port, a card socket (e.g., a memory card and a SIM/UIM card), or the like.

The second electronic module EM2 may include a sound output module AOM, a light emitting module LM, a light receiving module LRM, a camera module CMM, etc. The components may be mounted directly on the motherboard, or mounted on a separate board to be electrically connected to the display module 200 through a connector or the like, or electrically connected to the first electronic module EM1.

The sound output module AOM converts sound data received from the wireless communication module TM, or sound data stored in the memory MM, and outputs the converted result to the outside.

The light emitting module LM generates and outputs light. The light emitting module LM may output infrared ray. The light emitting module LM may include a LED element. The light receiving module LRM may detect infrared ray. The light receiving module LRM may be activated when infrared ray having a level (e.g., a set or predetermined level) or greater is detected. The light receiving module LRM may include a CMOS element. After the infrared light generated from the light emitting module LM is output, the infrared light may be reflected by an external object (e.g., a user's finger or face) and the reflected infrared light may be incident into the light receiving module LRM. The camera module CMM may photograph an external image.

Each of the first and second electronic module 501 and 502 according to some embodiments may include at least one of components of the first electronic module EM1 and/or the second electronic module EM2. For example, each of the first and second electronic module 501 and 502 may include at least one of the sound output module AOM, the light emitting module LM, the light receiving module LRM, the camera module CMM, or a heat detection module. The first and second electronic modules 501 and 502 may detect an external subject received through the second display area DA2 (illustrated in FIG. 1B), or provide the outside with a sound signal such as voice, or light such as infrared ray, through the second display area DA2.

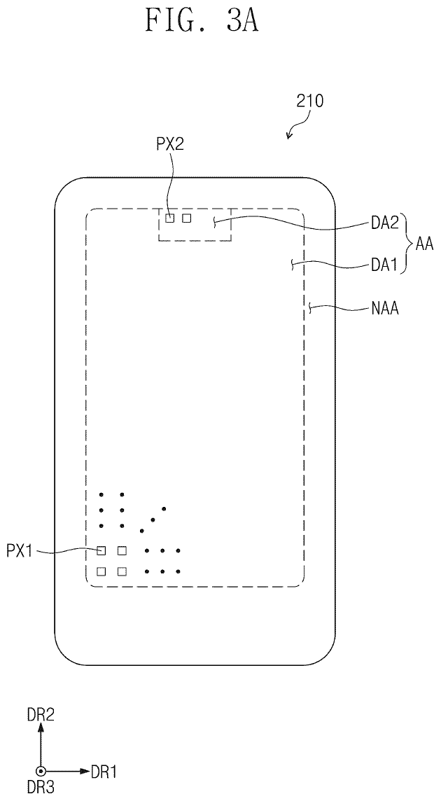

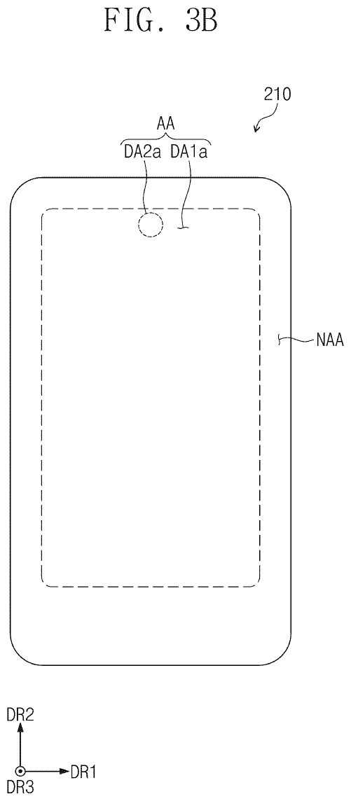

FIG. 3A is a plan view of a display panel according to some embodiments of the present disclosure.

Referring to FIGS. 1B and 3A, a first display area DA1 and a second display area DA2 may be defined in a display panel 210. The first display area DA1 and the second display area DA2 may correspond to the active area AA of the display module 200.

Electronic modules 500 may be located below the second display area DA2. A light transmittance of the second display area DA2 may be greater than a light transmittance of the first display area DA1. Thus, a signal may be transmitted and/or received by the electronic modules 500 through the second display area DA2. In order to increase the light transmittance, some components of the second display area DA2 may be omitted. For example, some of pixels located in the second display area DA2 may be removed and/or spaced relatively further apart.

The first display area DA1 and the second display area DA2 may be adjacent to each other. The second display area DA2 may have a rectangular shape, and at least one side that defines the second display area DA2 may be adjacent to the first display area DA1. FIG. 3A illustrates aspects of some embodiments of the present disclosure in which three sides are adjacent to the first display area DA1, and the other side is adjacent to the second display area DA2. However, embodiments according to the present disclosure are not limited thereto. In addition, according to some embodiments, the second display area DA2 may be defined on an upper portion of the display panel 210 when viewed on a plane (or in a plan view).

First pixels PX1 may be located in the first display area DA1, and second pixels PX2 may be located in the second display area DA2. The first pixels PX1 and the second pixels PX2 may be pixels that generate light. The number of the first pixels PX1 and the number of the second pixels PX2 in the same surface area may be different from each other. For example, the number of the second pixels PX1 may be smaller than the number of the first pixels PX2. Thus, the light transmittance of the second display area DA2 may be greater than the light transmittance of the first display area DA1. In addition, a resolution of the second display area DA2 may be less than a resolution of the first display area DA1.

The first and second pixels PX1 and PX2 may have substantially the same components. The components of the first and second pixels PX1 and PX2 will be described later with reference to the drawings.

FIG. 3B is a plan view of a display panel according to some embodiments of the present disclosure.

In the description with reference to FIG. 3B, the components described with reference to FIG. 3A are designated by the similar reference symbols, and some repetitive descriptions thereof may be omitted.

Referring to FIGS. 1B and 3B, a first display area DA1a and a second display area DA2a may be defined in a display panel 210. Electronic modules 500 may be located below the second display area DA2a. The second display area DA2a may be surrounded by the first display area DA1a.

FIGS. 3A and 3B illustrate examples in which the number of the second display area DA2a is one, but embodiments according to the present disclosure are not limited thereto. That is, according to some embodiments, two or more second display areas DA2a may be provided. In this case, the two or more second display areas DA2a may have the same light transmittance. However, embodiments according to the present disclosure are not limited thereto. That is, the two or more second display areas DA2a may have different transmittances from each other.

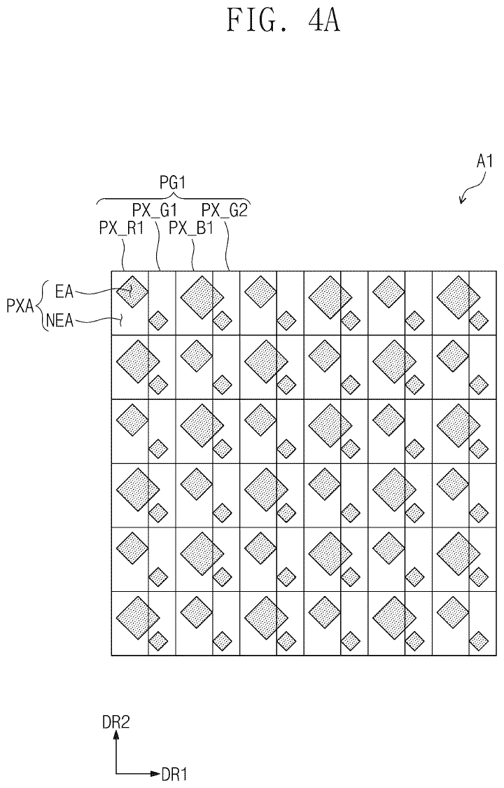

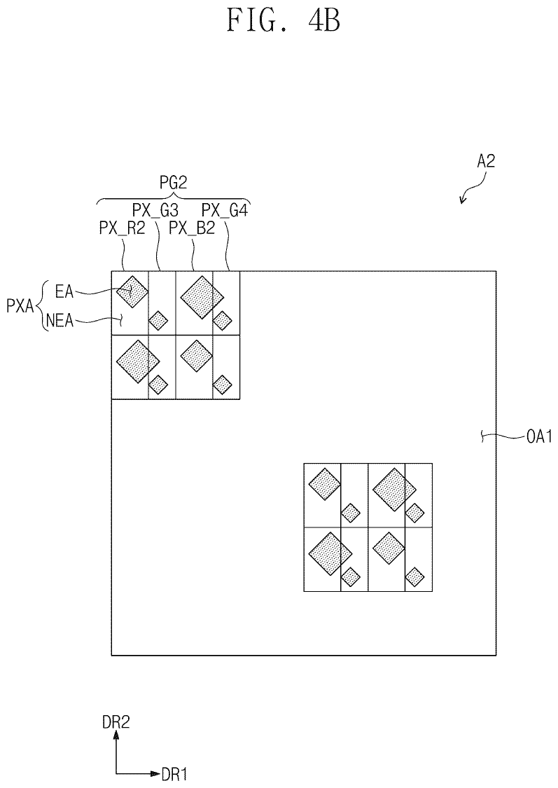

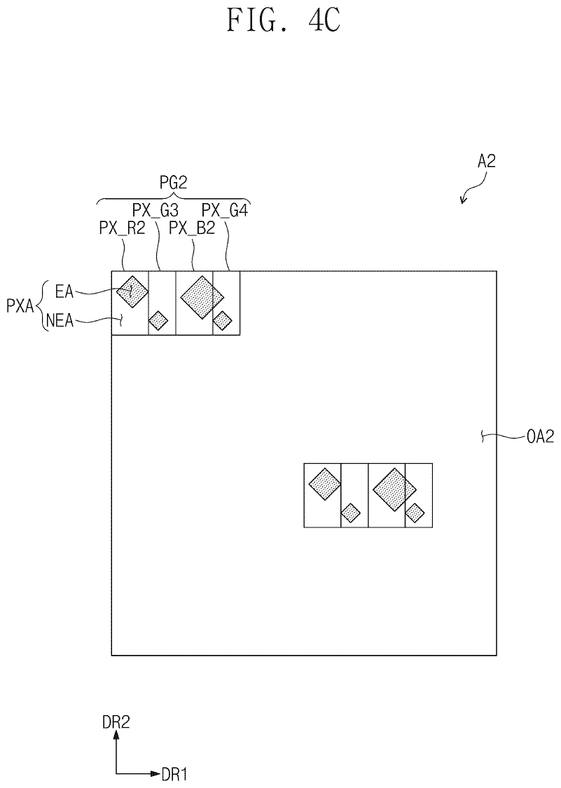

FIG. 4A is an enlarged plan view illustrating a portion of a first display area according to some embodiments of the present disclosure. FIG. 4B is an enlarged plan view illustrating a portion of a second display area according to some embodiments of the present disclosure.

Referring to FIGS. 3A and 4A, a plurality of first pixels PX1 may be located in a first display area DA1. The first pixels PX1 may be arranged to be spaced apart from each other in the first direction DR1 and the second direction DR2.

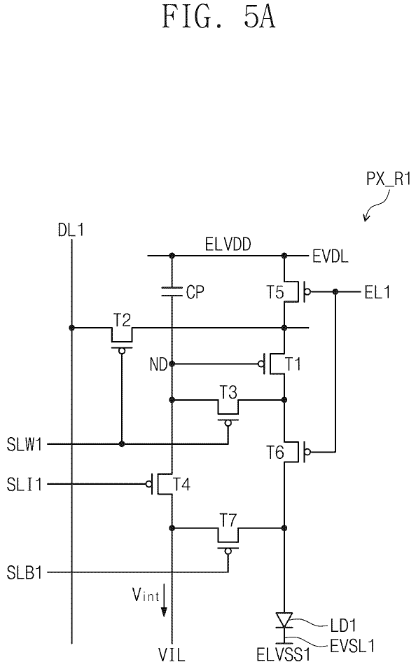

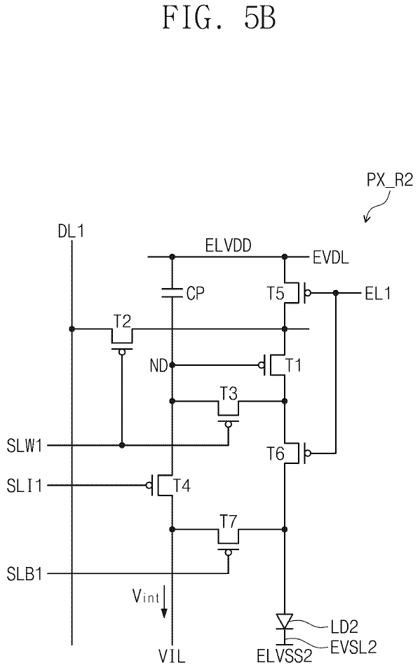

The first pixels PX1 may include a plurality of red pixels PX_R1, a plurality of green pixels PX_G1 and PX_G2, and a plurality of blue pixels PX_B1. The first pixels PX1 may be grouped into a plurality of first pixel groups PG1. For example, each of the first pixel groups PG1 may include one first red pixel PX_R1, two first green pixels PX_G1 and PX_G2, and one first blue pixel PX_B1. Each of the first pixels PX1 of the first pixel group PG1 may include an emission area EA and a non-emission area NEA. According to some embodiments, the emission area EA may have a rectangular shape. but is not limited thereto. A first light emitting element LD1 (illustrated in FIG. 5A) may be located in the emission area EA, and transistors T1 to T7 (illustrated in FIG. 5A) for driving the first light emitting element LD1 (illustrated in FIG. 5A) may be located in the non-emission area NEA.

The plurality of first pixel groups PG1 may be located in a first area A1 of the first display area DA1. The first area A1 may mean a unit area. For example, the first area A1 may have a surface area of about 1 inch x about 1 inch.

The first pixel groups PG1 may be arranged in a matrix shape within the first area A1. For example, the plurality of first pixel groups PG1 may be arranged to be spaced apart from each other in the first direction DR1 and the second direction DR2.

The first area A1 in which 18 first pixel groups PG1 are arranged is illustrated. However, the first area A1 is just illustrative for convenience of explanation, and embodiments according to the present disclosure are not limited thereto. The number of the first pixel groups PG1 located in the first area A1 may be increased.

Referring to FIGS. 3A and 4B, a plurality of second pixels PX2 may be located in a second area A2 of the second display area DA2. The second area A2 may include pixel areas PXA each having the plurality of second pixels PX2 located, and a plurality of opening areas OA1. The pixels may not be substantially arranged in the opening areas OA1. That is, the opening areas OA1 may be an area in which some components of the second pixels PX2 (e.g., second light emitting element LD2 (illustrated in FIG. 5B) are removed. Thus, the resolution of the first display area DA1 may be greater than the resolution of the second display area DA2 in the unit area.

The second pixels PX2 may have the same structure as the first pixels PX1. The second pixels PX2 may be grouped into a plurality of second pixel groups PG2.

For example, each of the second pixel groups PG2 may include one second red pixel PX_R2, two second green pixels PX_G3 and PX_G4, and one second blue pixel PX_B2. Each of the pixel areas PXA may include an emission area EA and a non-emission area NEA. According to some embodiments, the emission area EA may have a rectangular shape. but is not limited thereto. A second light emitting element LD2 (illustrated in FIG. 5B) may be located in the emission area EA, and transistors T1 to T7 (illustrated in FIG. 5B) for driving the second light emitting element LD2 may be located in the non-emission area NEA.

The second area A2 may be defined as a unit area like the first area A1. That is, the second area A2 and the first area A1 may have the same surface area.

Four second pixel groups PG2 may be located in the second area A2. In the second area A2, portions other than the pixel areas PXA in which the second pixel groups PG2 are located may be defined as the opening areas OA1. Each of the opening areas OA1 may be a light path through which light provided from the outside is transmitted. Accordingly, sensors located in the second display area DA2 may recognize the light transmitted through the opening area OA1 to detect a user's input information.

In the second area A2, a total surface area of the pixel areas PXA may be smaller than a total surface area of the opening areas OA1.

Referring to FIG. 4C, two second pixel groups PG2 may be located in a second area A2. In the second area A2, portions other than pixel areas PXA in which the second pixel groups PG2 are located may be defined as an opening area OA2. The opening area OA2 of the second area A2 illustrated in FIG. 4C may have a larger surface area than the opening area OA1 of the second area A2 illustrated in FIG. 4B. Accordingly, a light recognition rate, sensing sensitivity, and the like of the sensors located in the second display area DA2 may be relatively improved.

FIG. 5A is an equivalent circuit diagram of a first red pixel according to some embodiments of the present disclosure. Although various components are illustrated in FIG. 5A, embodiments according to the present disclosure are not limited thereto. For example, according to some embodiments, the first red pixel may include additional components or fewer components without departing from the spirit and scope of embodiments according to the present disclosure.

Referring to FIG. 5A, a first red pixel PX_R1 may include a plurality of transistors T1 to T7, a capacitor CP, and a first light emitting element LD1. The plurality of transistors T1 to T7 and the capacitor CP may control an amount of current flowing through the first light emitting element LD1 in response to a data signal and a scan signal.

Each of the plurality of transistors T1 to T7 may include an input electrode (or source electrode), an output electrode (or drain electrode), and a control electrode (or gate electrode). One of the input electrode and the output electrode is defined as a first electrode, and the other is defined as a second electrode herein for convenience.

A first electrode of the first transistor T1 may be connected to a driving power line EVDL via the fifth transistor T5. The driving power line EVDL may be a line through which a driving power voltage ELVDD is supplied. A second electrode of the first transistor T1 is connected to an anode electrode of the first light emitting element LD1 via the sixth transistor T6.

The first transistor T1 may control an amount of current flowing through the first light emitting element LD1 corresponding to a voltage applied to the control electrode of the first transistor T1.

The second transistor T2 may be connected between a data line DL1 and the first electrode of the first transistor T1. A control electrode of the second transistor T2 is connected to a second scan line SLW1. When a second scan signal is provided to the second scan line SLW1, the second transistor T2 may be turned on to electrically connect the data line DL1 to the first electrode of the first transistor T1.

The third transistor T3 may be connected between the second electrode of the first transistor T1 and the control electrode of the first transistor T1. A control electrode of the third transistor T3 is connected to the second scan line SLW1. When the second scan signal is provided to the second scan line SLW1, the third transistor T3 may be turned on to electrically connect the second electrode of the first transistor T1 to the control electrode of the first transistor T1. Thus, when the third transistor T3 is turned on, the first transistor T1 is diode-connected.

The fourth transistor T4 is connected between a node ND and an initialization voltage line VIL. A control electrode of the fourth transistor T4 is connected to a first scan line SLI1. The node ND may a node to which the fourth transistor T4 and the control electrode of the first transistor T1 are connected. When a first scan signal is provided to the first scan line SLI1, the fourth transistor T4 may be turned on to supply an initialization voltage Vint to the node ND. Here, the first scan signal may be a signal that is earlier generated than the second scan signal. For example, the first scan signal may be the same signal as a signal applied to the second scan line SLW1 of a pixel in a previous row.

The fifth transistor T5 may be connected between the driving power line EVDL and the first electrode of the first transistor T1. The sixth transistor T6 may be connected between the second electrode of the first transistor T1 and the anode electrode of the first light emitting element LD1. A control electrode of the fifth transistor T5 and a control electrode of the sixth transistor T6 are connected to a first emission control line EL1.

The seventh transistor T7 is connected between the initialization voltage line VIL and the anode electrode of the first light emitting element LD1. A control electrode of the seventh transistor T7 is connected to a third scan line SLB1. When a third scan signal is provided to a third scan line SLB1, the seventh transistor T7 may be turned on to supply the initialization voltage Vint to the anode electrode of the first light emitting element LD1. For example, the third scan signal may be the same signal as a signal applied to the second scan line SLI1 of a pixel in a next row.

Additionally, FIG. 5A illustrates the control electrode of the seventh transistor T7 being connected to the third scan line SLB12, but embodiments according to the present disclosure are not limited thereto. According to some embodiments, the control electrode of the seventh transistor T7 may be connected to the second scan line SLW1.

FIG. 5A illustrates embodiments in which the first to seventh transistors T1 to T7 are PMOS transistors, but embodiments according to the present disclosure are not limited thereto. According to some embodiments, some or all of the first to seventh transistors T1 to T7 are provided as PMOS transistors.

The capacitor CP is located between the driving power line EVDL and the node ND. The capacitor CP stores a voltage corresponding to a data signal. When the fifth transistor T5 and the sixth transistor T6 are turned on in response to the voltage stored in the capacitor CP, an amount of current flowing through the first transistor T1 may be determined.

The first light emitting element LD1 may be electrically connected to the sixth transistor T6 and a first source power line EVSL1. A first anode electrode of the first light emitting element LD1 may be connected to the sixth transistor T6, and the first cathode electrode of the first light emitting element LD1 may be connected to the first source power line EVSL1. A first source power voltage ELVSS1 may be applied to the first source power line EVSL1. The first source power voltage ELVSS1 has a lower level than the driving power voltage ELVDD. Thus, the first light emitting element LD1 may emit light in response to a voltage corresponding to a difference between a signal transmitted through the sixth transistor T6 and the first source power voltage ELVSS1.

According to some embodiments, a structure of the first red pixel PX_R1 is not limited to the structure illustrated in FIG. 5A. According to some embodiments, the first red pixel PX_R1 may be embodied in various forms for allowing the first light emitting element LD1 to emit light.

FIG. 5B is an equivalent circuit diagram of a second red pixel according to some embodiments of the present disclosure. Although various components are illustrated in FIG. 5B, embodiments according to the present disclosure are not limited thereto. For example, according to some embodiments, the second red pixel may include additional components or fewer components without departing from the spirit and scope of embodiments according to the present disclosure.

The components described with reference to FIG. 5A are designated by the similar reference numbers or symbols, and descriptions thereof are omitted.

Referring to FIGS. 5A and 5B, a second red pixel PX_R2 may include a plurality of transistors T1 to T7, a capacitor CP, and a second light emitting element LD2. The plurality of transistors T1 to T7 and the capacitor CP may control an amount of current flowing through the second light emitting element LD2 in response to a data signal and a scan signal.

In particular, a second cathode electrode of the second light emitting element LD2, unlike the first cathode electrode of the first light emitting element LD1, may be connected to a second source power line EVSL2 to receive a second source power voltage ELVSS2. According to some embodiments, the second source power voltage ELVSS2 may have a lower voltage level than the first source power voltage ELVSS1. As one example, when the first source power voltage ELVSS1 is −6V, the second source power voltage ELVSS2 may have a voltage less than −6V, and the second source power voltage ELVSS2 may have a voltage of −6.7V.

Thus, the second light emitting element LD2 may emit light in response to a voltage corresponding to a difference between a signal transmitted through the sixth transistor T6 and the second source power voltage ELVSS2. That is, even when a signal having the same level as the signal input into the first cathode electrode of the first light emitting element LD1 is transmitted to a second anode electrode of the second light emitting element LD2, driving current of the second light emitting element LD2 is increased by a different between the second source power voltage ELVSS2 and the first source power voltage ELVSS1. Thus, under the same input signal, the second light emitting element LD2 may emit light having high luminance than the first light emitting element LD1. As a result, a sharpness of the second display area DA2 may be relatively improved.

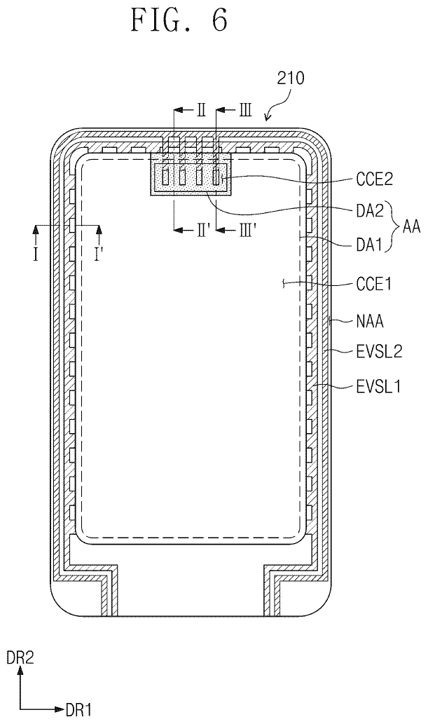

In addition, as described in more detail below, according to some embodiments, the first source power line EVSL1 and the second source power line EVSL2, and a first common cathode electrode CCE1 (see FIG. 6) and a second common cathode electrode CCE2 (see FIG. 6), are separated so that the first source power voltage ELVSS1 received through the first source power line EVSL1 by the first light emitting element LD1, is provided to be different from the second source power voltage ELVSS2 received through the second source power line EVSL2 by the second light emitting element LD2.

Accordingly, the first source power line EVSL1 and the second source power line EVSL2 may be provided to be integrated to prevent or reduce a voltage loss occurring as the same source power voltage is supplied to the first light emitting element LD1 and the second light emitting element LD2. That is, as the first source power line EVSL1 and the second source power line EVSL2 are separated, a voltage, which is determined considering a voltage drop (IR-DROP) value of the lines, may be supplied to each of the lines. Accordingly, power consumption of the display device DD (see FIG. 1A) may be relatively reduced.

For example, when a voltage drop value of the first source power line EVSL1 is greater than a voltage drop value of the second source power line EVSL2, not the voltage drop value of the first source power line EVSL1 but the voltage drop value of the second source power line EVSL2 may be considered for the second source power voltage ELVSS2 supplied to the second source power line EVSL2.

In addition, as separate power lines and cathode electrodes are used, the voltage drop value of some lines may be decreased to decrease the level of the driving voltage supplied to each of the lines. Accordingly, the power consumption of the display device DD (see FIG. 1A) may be further relatively reduced.

FIG. 6 is a plan view of a display panel according to some embodiments of the present disclosure. For example, FIG. 6 is a plan view illustrating a line layout of a display panel according to some embodiments of the present disclosure.

Referring to FIG. 6, an active area AA of a display panel 210 may be an area on which an image is displayed, and a peripheral area NAA thereof may be an area on which a driving circuit, a driving line, or the like is located. In FIG. 6, the active area AA of the display panel 210 includes first and second display areas DA1 and DA2.

According to some embodiments, the second display area DA2 may be surrounded by the first display area DA1, but embodiments according to the present disclosure are not limited to that illustrated in the drawing. For example, only a portion of the second display area DA2 may be surrounded by the first display area DA1, and the other portion may be surrounded by the peripheral area NAA. However, embodiments according to the present disclosure are not limited thereto.

In addition, the second display area DA2 is illustrated as having a rectangular shape in the drawing, but embodiments according to the present disclosure are not limited thereto. For example, the second display area DA2 may have a circular shape, an elliptical shape, a polygonal shape, an irregular shape, and the like.

A first common cathode electrode CCE1 is located in the first display area DA1, and a second common cathode electrode CCE2 is located in the second display area DA2. The first and second cathode electrodes CCE1 and CCE2 may be arranged to be spaced apart and electrically insulated from each other.

The first common cathode electrode CCE1 may be defined as an electrode that is provided by connecting, in common, the first cathode electrodes of the first light emitting elements LD1 provided in the first pixels PX1 illustrated in FIGS. 3A and 5A. That is, the first cathode electrodes of the first light emitting elements LD1 may be provided as one body to be provided in the form of a single-body electrode like the first common cathode electrode CCE2.

The second common cathode electrode CCE2 may be defined as an electrode that is provided by connecting, in common, the second cathode electrodes of the second light emitting elements LD2 provided in the second pixels PX2 illustrated in FIGS. 3A and 5A. That is, the second cathode electrodes of the second light emitting elements LD2 may be provided as one body to be provided in the form of a single-body electrode like the second common cathode electrode CCE2.

The first common cathode electrode CCE1 and the second common cathode electrode CCE2 may overlap each other in the second display area DA2. However, embodiments according to the present disclosure are not limited thereto. For example, the second common cathode electrode CCE2 may extend to the first display area DA1 so that the first common cathode electrode CCE1 and the second common cathode electrode CCE2 overlaps each other also in the first display area DA1.

A first source power line EVSL1 electrically connected to the first common cathode electrode CCE1, and a second source power voltage ELVSS2 electrically connected to the second common cathode electrode CCE2 are located in the peripheral area NAA. The first and second source power lines EVSL1 and EVSL2 may be arranged so as to surround three sides of the active area AA. Pads extending from both ends of each of the first and second source power lines EVSL1 and EVSL2 may be located in the peripheral area NAA on which the pads PD (illustrated in FIG. 1B) are located.

As illustrated in FIG. 6, the first source power line EVSL1 may be located inside the second source power line EVSL2. That is, the phrase “being located inward” used herein means that the first source power line EVSL1 is arranged to be more adjacent to the active area AA than the second source power line EVSL2 is.

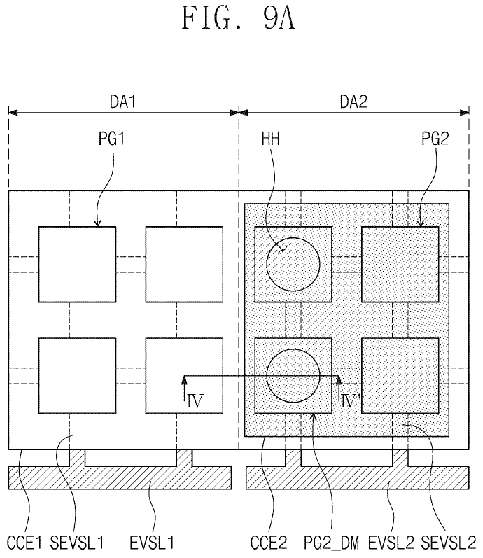

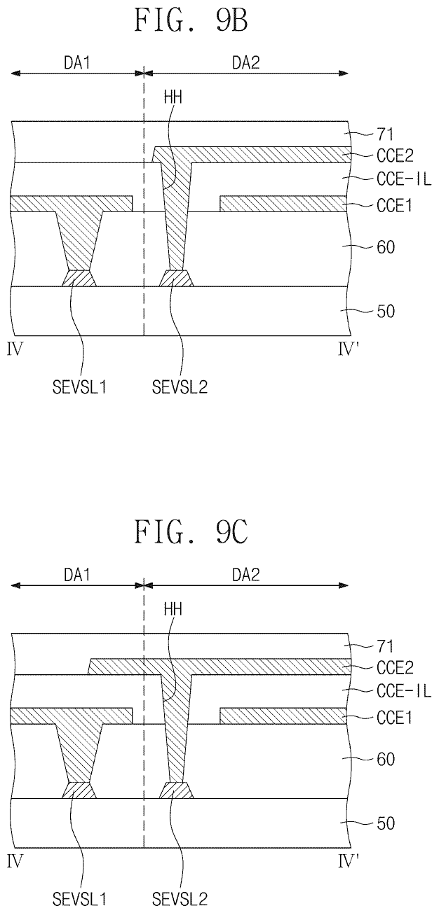

According to some embodiments, the first source power line EVSL1 is electrically connected to the first common cathode electrode CCE1 through a first power auxiliary line SEVSL1 (see FIG. 9A), and the second source power line EVSL2 is electrically connected to the second common cathode electrode CCE2 through a second power auxiliary line SEVSL2 (see FIG. 9A).

The first power auxiliary line SEVSL1 (see FIG. 9A) may be branched from the first source power line EVSL1 to extend to a side of the first display area DA1. The second power auxiliary line SEVSL2 (see FIG. 9A) may be branched from the second source power line EVSL2 to extend to a side of each of the first display area DA1 and the second display area DA2.

According to some embodiments, the second power auxiliary line SEVSL2 (see FIG. 9A) may be branched from one position of the second source power line EVSL2 so as to have a minimum distance from the second source power line EVSL2 to the second display area DA2. In addition, the second power auxiliary line SEVSL2 (see FIG. 9A) may extend in a direction in which the second power auxiliary line SEVSL2 has the minimum distance to the second display area DA2.

That is, the second power auxiliary line SEVSL2 (see FIG. 9A) may extend along the first display area DA1 so that a distance between the second display area DA2 and the peripheral area NAA is a minimum distance. However, embodiments according to the present disclosure are not limited thereto. For example, the second power auxiliary line SEVSL2 (see FIG. 9A) may extend in a different direction.

The length and the extending direction of the second power auxiliary line SEVSL2 (see FIG. 9A) may vary according to the shape of the second display area DA2 and the distance between the second display area DA2 and the peripheral area NAA according to product design. However, embodiments according to the present disclosure are not limited thereto.

The first power auxiliary line SEVSL1 (see FIG. 9A) may include a left power auxiliary line and a right power auxiliary line that are separated on the basis of the second display area DA2. The first power auxiliary line SEVSL1 (see FIG. 9A) and the second power auxiliary line SEVSL2 (see FIG. 9A) are arranged to be spaced apart from each other, and electrically insulated from each other.

Each of the number of the first power auxiliary line SEVSL1 (see FIG. 9A) and the number of the second power auxiliary line SEVSL2 (see FIG. 9A) is not limited to that illustrated in the drawing, and may be less or greater than that illustrated in the drawing. However, embodiments according to the present disclosure are not limited to any one embodiment.

As illustrated in FIG. 6, the first common cathode electrode CCE1 may overlap the first display area DA1 and the second display area DA2. In addition, the first common cathode electrode CCE1 may extend to the peripheral area NAA. The second common cathode electrode CCE2 may overlap the second display area DA2. In addition, the second common cathode electrode CCE2 may overlap the first display area DA1, and extend to the peripheral area NAA. However, embodiments according to the present disclosure are not limited the embodiments illustrated in the FIG. 6. For example, the first common cathode electrode CCE1 may not overlap the peripheral area NAA, and the second common cathode electrode CCE2 may not overlap the first display area DA1. Embodiments according to the present disclosure are not limited to any one embodiment.

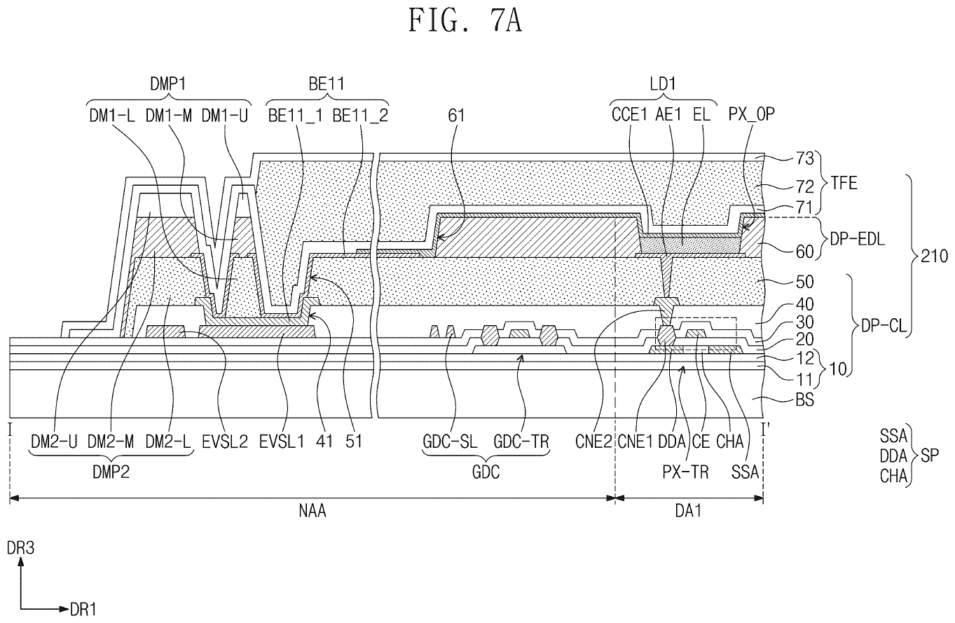

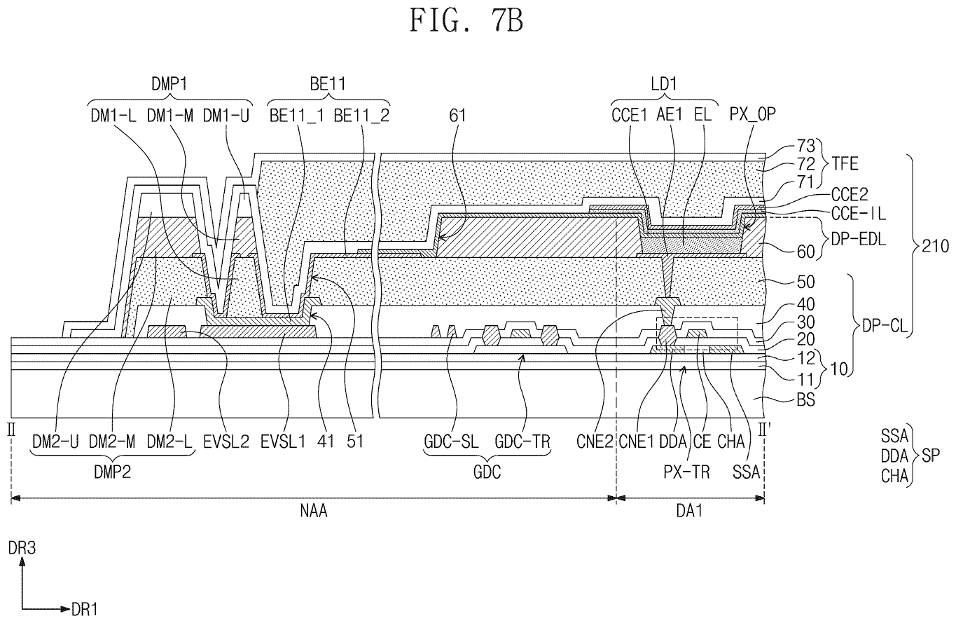

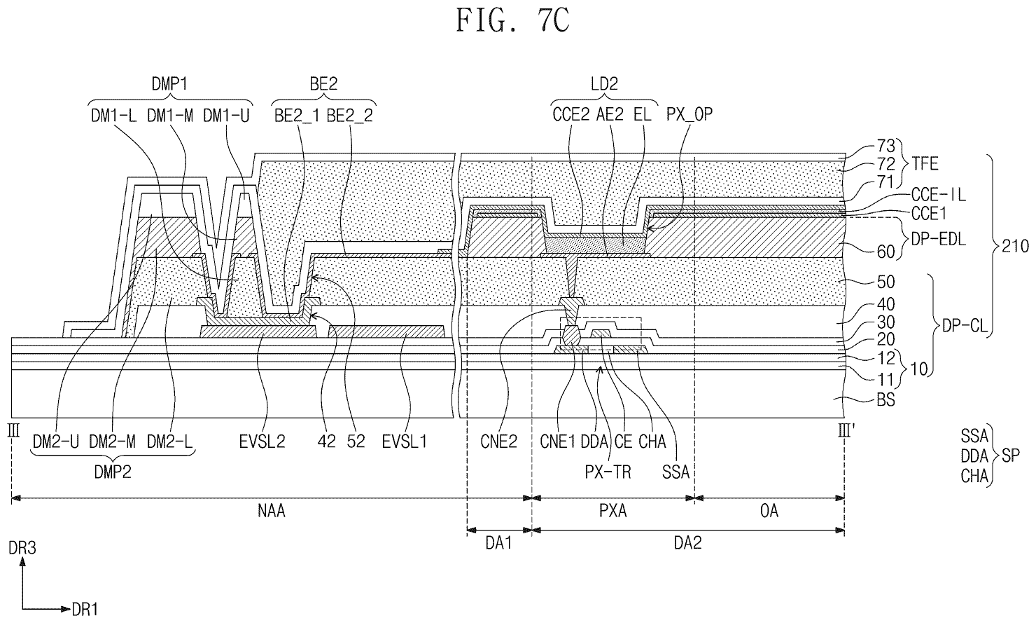

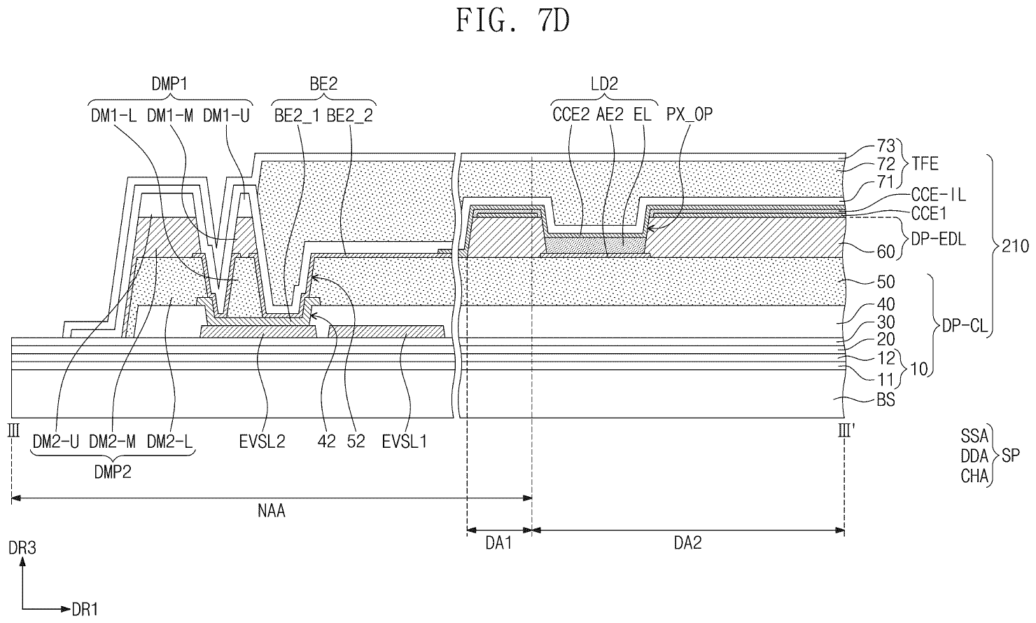

FIGS. 7A to 7D are cross-sectional views of a display panel according to some embodiments of the present disclosure. For example, FIG. 7A is a cross-sectional view taken along the line I-I′ illustrated in FIG. 6, FIG. 7B is a cross-sectional view taken along the line II-II′ illustrated in FIG. 6, and FIGS. 7C and 7D are cross-sectional views taken along the line III-III′ illustrated in FIG. 6.

Referring to FIGS. 7A and 7B together, a display panel 210 includes a base layer BS, a circuit element layer DP-CL, a light emitting element layer DP-EDL, and a thin-film encapsulation layer TFE. According to some embodiments, the base layer BS, the circuit element layer DP-CL, the light emitting element layer DP-EDL, and the thin-film encapsulation layer TFE may be stacked in sequence in the third direction DR3.

The base layer BS may be a member that provides a base surface on which the circuit element layer DP-CL is located. The base layer BS may be a glass substrate, a metal substrate, a plastic substrate, or the like. However, embodiments according to the present disclosure are not limited thereto, and the base layer BS may be an inorganic layer, an organic layer, or a composite material layer.

The circuit element layer DP-CL is located on the base layer BS. The circuit element layer DP-CL may include the transistors T1 to T7 (see FIGS. 5A and 5B), the capacitor CP (see FIGS. 5A and 5B), and the like. FIGS. 7A and 7B illustrate only one transistor PX-TR (hereinafter referred to as a pixel transistor) for convenience of explanation. Here, the pixel transistor PX-TR may be the sixth transistor T6 described with reference to FIGS. 5A and 5B.

The circuit element layer DP-CL further includes first to sixth insulation layers 10, 20, 30, 40, 50 and 60 that are stacked in the third direction DR3. The first insulation layer 10 is located on the base layer BS. The first insulation layer 10 may include a barrier layer 11 and a buffer layer 12.

The barrier layer 11 may include an inorganic matter. The barrier layer 11 may prevent or reduce oxygen or moisture, which is introduced through the base layer BS, from permeating the pixels PX1 and PX2 (see FIG. 3A). The buffer layer 12 may include an inorganic matter. The buffer layer 12 may supply lower surface energy to the pixels PX1 and PX2 than the base layer BS so that the pixels PX1 and PX2 are stably provided on the base layer BS. In FIGS. 7A and 7B, each of the barrier layer 11 and the buffer layer 12 is illustrate as a single layer. However, this is illustrated as one example, and each of the barrier layer 11 and the buffer layer 12 according to some embodiments of the present disclosure may be provided in plurality so as to be alternately stacked. Alternatively, at least one of the barrier layer 11 or the buffer layer 12 may be provided in plurality, or may be omitted.

The transistor PX-TR may be located on the first insulation layer 10. The transistor PX-TR includes a semiconductor pattern SP and a control electrode CE. The semiconductor pattern SP is located on the first insulation layer 10. The semiconductor pattern SP may include a semiconductor material. The semiconductor pattern SP may include a channel part CHA, a source part SSA, and a drain part DDA. The semiconductor pattern SP may be covered by the second insulation layer 20, and the control electrode CE may be located on the second insulation layer 20. The control electrode CE is located on the second insulation layer 20 to correspond to the channel part CHA of the semiconductor pattern SP. That is, the control electrode CE and the channel part CHA of the semiconductor pattern SP are spaced apart from each other by the second insulation layer 20. The control electrode CE may be connected to one electrode of the capacitor CP.

The source part SSA and the drain part DDA of the semiconductor pattern SP may be spaced apart from each other with the channel part CHA therebetween. The source part SSA of the semiconductor pattern SP may be utilized as an input electrode of the transistor PX-TR, and the drain part DDA of the semiconductor pattern SP may be utilized as an output electrode of the transistor PX-TR.

The third insulation layer 30 is located on the control electrode CE and the second insulation layer 20. The second and third insulation layers 20 and 30 may be provided with a contact hole for exposing the drain part DDA of the semiconductor pattern SP. A first connection electrode CNE1 connected to the drain part DDA through the contact hole may be located on the third insulation layer 30. According to some embodiments, in FIG. 7A, the transistor PX-TR may further include an input electrode and an output electrode that are connected to the source part SSA and the drain part DDA of the semiconductor pattern SP, respectively.

The fourth insulation layer 40 is located on the third insulation layer 30. The fourth insulation layer 40 may include an organic matter and/or an inorganic matter, and may have a single-layer structure or a stacked structure.

A second connection electrode CNE2 may be located on the fourth insulation layer 40. The second connection electrode CNE2 may be connected to the first connection electrode CNE1. The fifth insulation layer 50 may be located on the second connection electrode CNE2.

The pixel transistor PX-TR according to some embodiments may be provided in various structures, and is not limited to the embodiments illustrated in FIGS. 7A and 7B.

The light emitting element layer DP-EDL is located on the circuit element layer DP-CL. The light emitting element layer DP-EDL may include a plurality of light emitting elements.

A first light emitting element LD1 of the light emitting elements is located on the fifth insulation layer 50. The first light emitting element LD1 may include a first anode electrode AE1, an emission layer EL, and a first common cathode electrode CCE1. The first anode electrode AE1 may pass through the fifth insulation layer 50 to be electrically connected to the pixel transistor PX-TR through the second connection electrode CNE2.

The sixth insulation layer 60 may be located on the fifth insulation layer 50. A pixel opening portion PX_OP may be defined in the sixth insulation layer 60, and the pixel opening portion PX_OP may expose at least a portion of the first anode electrode AE1. The sixth insulation layer 60 may be a pixel defining film.

The emission layer EL may be located on the first anode electrode AE1 exposed by the pixel opening portion PX_OP defined in the sixth insulation layer 60. The emission layer EL may include a light emitting material. For example, the emission layer EL may include at least one material of materials emitting light having a red color, a green color, or a blue color. The emission layer EL may include a fluorescent material or a phosphorescent material. The emission layer EL may include an organic light emitting material or an inorganic light emitting material. The emission layer EL may emit light in response to a potential difference between the first anode electrode AE1 and the first common cathode electrode CCE1.

The first common cathode electrode CCE1 may be located on the emission layer EL. The first common cathode electrode CCE1 may be provided, in common, in a plurality of first pixels PX1. The first common cathode electrode CCE1 may have a shape corresponding to the first display area DA1. The first common cathode electrode CCE1 may be electrically connected to a first source power line EVSL1 located in a peripheral area NAA.

A cathode insulation layer CCE-IL may be located on the first common cathode electrode CCE1. The cathode insulation layer CCE-IL may be located between the first common cathode electrode CCE1 and a second common cathode electrode CCE2. For example, the cathode insulation layer CCE-IL may be located on the first common cathode electrode DA1 on the first display area DA1. In addition, the cathode insulation layer CCE-IL may be located on the first common cathode electrode DA2 on the second area DA2 (see FIG. 6).

The cathode insulation layer CCE-IL may have a shape corresponding to the first display area DA1. However, embodiments according to the present disclosure are not limited thereto. For example, the cathode insulation layer CCE-IL may have a shape that covers the entirety of the second display area DA2 and a portion of the first display area DA1, but embodiments according to the present disclosure are not limited thereto.

The cathode insulation layer CCE-IL may separate the first common cathode electrode CCE1 and the second common cathode electrode CCE2 from each other so that the first common cathode electrode CCE1 and the second common cathode electrode CCE2 are electrically insulated from each other.

The second common cathode electrode CCE2 may be located on the cathode insulation layer CCE-IL. The second common cathode electrode CCE2 will be described later in detail.

According to some embodiments of the present disclosure, the first source power line EVSL1 and the first connection electrode CNE1 are located on the same layer. When the transistor PX-TR includes input and output electrodes, the first source power line EVSL1 is located on the same layer as the input and output electrodes of the transistor PX-TR. Each of the fourth and fifth insulation layers 40 and 50 is provided with first and second contact parts 41 and 51 for exposing the first source power line EVSL1. The first and second contact parts 41 and 51 may be defined as areas in which the fourth and fifth insulation layers 40 and 50 are opened to correspond to the first source power line EVSL1.

A first bridge electrode BE11 is located on the first source power line EVSL1 exposed through the first and second contact parts 41 and 51. The first bridge electrode BE11 may be part of the first power auxiliary line SEVSL1 (see FIG. 9A) described above. The first bridge electrode BE11 may include a first sub-bridge electrode BE11_1 and a second sub-bridge electrode BE11_2.

The first sub-bridge electrode BE11_1 is located on the first source power line EVSL1 and the fourth insulation layer 40. That is, the first sub-bridge electrode BE11_1 and the second connection electrode CNE2 may be located on the same layer. The first sub-bridge electrode BE11_1 is in direct contact with the first source power line EVSL1 exposed through the first contact part 41.

The second sub-bridge electrode BE11_2 is located on the first sub-bridge electrode BE11_1 and the fifth insulation layer 50. That is, the second sub-bridge electrode BE11_2 and the first anode electrode AE1 may be located on the same layer. The second sub-bridge electrode BE11_2 is in direct contact with the first sub-bridge electrode BE11_1 exposed through the second contact part 51.

On a plane (or in a plan view), the first source power line EVSL1 partially overlaps the first bridge electrode BE11, and the first common cathode electrode CCE1 partially overlaps the first bridge electrode BE11. The first common cathode electrode CCE1 may overlap the first bridge electrode BE11 in the peripheral area NAA.

According to some embodiments of the present disclosure, the fifth insulation layer 50 may be omitted. In a structure in which the fifth insulation layer 50 is omitted, the first bridge electrode BE11 may include only the second sub-bridge electrode BE11_2. In this case, the second sub-bridge electrode BE11_2 may be in direct contact with the first source power line EVSL1.

The sixth insulation layer 60 is provided with a third contact part 61 for exposing the second sub-bridge electrode BE11_2. The first common cathode electrode CCE1 located on the sixth insulation layer 60 may be in direct contact with the second sub-bridge electrode CCE1 in the third contact part 61.

As illustrated in FIG. 7A, a scan driver GDC connected to the first to third scan lines SLI1, SLW1 and SLB1 (see FIGS. 5A and 5B) of the first and second pixels PX1 and PX2 may be located between the first source power line EVSL1 and the first display area DA1. That is, the first and second source power lines EVSL1 and EVSL2 may be located outside the scan driver GDC. Here, the phrase “being located outside” refers to the first and second source power lines EVSL1 and EVSL2 being located farther from the active area AA than the scan driver GDC. The scan driver GDC may include signal lines GDC-SL and transistors for driving GDC-TR.

Referring to FIG. 7C, a second light emitting element LD2 is located on a fifth insulation layer 50. The second light emitting element LD2 may include a second anode electrode AE2, an emission layer EL, and a second common cathode electrode CCE2. The second anode electrode AE2 may pass through the fifth insulation layer 50 to be electrically connected to a pixel transistor PX-TR through the second connection electrode CNE2. The emission layer EL may emit light in response to a potential difference between the second anode electrode AE2 and the second common cathode electrode CCE2.

FIG. 7D illustrates a case in which a second light emitting element LD2 is a dummy unlike the second light emitting element LD2 according to some embodiments of the present disclosure illustrated in FIG. 7C. Referring to FIG. 7D, a second anode electrode AE2 may be electrically insulated from the pixel transistor PX-TR (see FIG. 7C).

Referring to FIGS. 7C and 7D, the second common cathode electrode CCE2 may be located on a cathode insulation layer CCE-IL. The second common cathode electrode CCE2 may be located on the cathode insulation layer CCE-IL to be electrically insulated from a first common cathode electrode CCE1.

In addition, the second common cathode electrode CCE2 may be located on the emission layer EL. The second common cathode electrode CCE2 may be provided, in common, in the plurality of second pixels PX2 (illustrated in FIG. 3A). The second common cathode electrode CCE2 may have a shape corresponding to the second display area DA2. However, embodiments of the present disclosure are not limited thereto. For example, the second common cathode electrode CCE2 may have a shape corresponding to the entirety of the second display area DA2 and a portion of the first display area DA1, but embodiments according to the present disclosure are not limited thereto. The second common cathode electrode CCE2 may be electrically connected to a second source power line EVSL2 located in a peripheral area NAA.

According to some embodiments of the present disclosure, before the second common cathode electrode CCE2 is formed, the first common cathode electrode CCE1 may be formed, and then a portion of the first common cathode electrode CCE1, which overlaps the emission layer EL of the second light emitting element LD2, may be removed. Thereafter, the cathode insulation layer CCE-IL and the second common cathode electrode CCE2 may be formed. Here, the first common cathode electrode CCE1 may be removed by a laser drilling method, and embodiments according to the present disclosure are not limited thereto.

However, embodiments according to the present disclosure are not limited thereto. For example, after the first common cathode electrode CCE1 and the cathode insulation layer CCE-IL are formed, a portion of the first common cathode electrode CCE1 and a portion of the cathode insulation layer CCE-IL, each of which overlaps the emission layer EL of the second light emitting element LD2, may be removed to form the second common cathode electrode CCE2 thereon, and embodiments according to the present disclosure are not limited to any one embodiment.

According to some embodiments of the present disclosure, the second source power line EVSL2 and the first connection electrode CNE1 are located on the same layer. Each of the fourth and fifth insulation layers 40 and 50 is provided with fourth and fifth contact parts 42 and 52 for exposing the first source power line EVSL2. The fourth and fifth contact parts 42 and 52 may be defined as areas in which the fourth and fifth insulation layers 40 and 50 are opened to correspond to the second source power line EVSL2.

A second bridge electrode BE2 is located on the second source power line EVSL2 exposed through the fourth and fifth contact parts 42 and 52. The second bridge electrode BE2 may be part of the second power auxiliary line SEVSL2 (see FIG. 9A) described above. The second bridge electrode BE2 includes a third sub-bridge electrode BE2_1 and a fourth sub-bridge electrode BE2_2.

The third sub-bridge electrode BE2_1 is located on the second source power line EVSL2 and the fourth insulation layer 40. That is, the third sub-bridge electrode BE2_1 and the second connection electrode CNE2 may be located on the same layer. The third sub-bridge electrode BE2_1 is in direct contact with the second source power line EVSL2 exposed through the fourth contact part 42.

The fourth sub-bridge electrode BE2_2 is located on the third sub-bridge electrode BE2_1 and the fifth insulation layer 50. That is, the fourth sub-bridge electrode BE2_2 and the second anode electrode AE2 may be located on the same layer. The fourth sub-bridge electrode BE2_2 may be in direct contact with the third sub-bridge electrode BE2_1 exposed through the fifth contact part 52.

On a plane (or in a plan view), the second source power line EVSL2 partially overlaps the second bridge electrode BE2, and the second common cathode electrode CCE2 partially overlaps the second bridge electrode BE2. The second bridge electrode BE2 may also partially overlap the first source power line EVSL1 in an area adjacent to the second display area DA2. The second common cathode electrode CCE2 may overlap the second bridge electrode BE2 in the peripheral area NAA.

According to some embodiments of the present disclosure, the fifth insulation layer 50 may be omitted. In a structure in which the fifth insulation layer 50 is omitted, the second bridge electrode BE2 may include only the fourth sub-bridge electrode BE2_2. In this case, the fourth sub-bridge electrode BE2_2 may be in direct contact with the second source power line EVSL2.

A sixth insulation layer 60 is provided with a sixth contact part for exposing the fourth sub-bridge electrode BE2_2. The second common cathode electrode CCE2 located on the sixth insulation layer 60 may be in direct contact with the fourth sub-bridge electrode CCE1 in the sixth contact part.

As illustrated in FIG. 7C, the scan driver GDC may not be located between the first source power line EVSL1 and the first display area DA1.

In addition, as illustrated in FIGS. 4B and 7C, the transistor PX-TR and the second light emitting element LD2 may not be located in the opening area OA1 of the second display area DA2. Only the base layer BS and the first to sixth insulation layers 10 to 60 may be present in the opening area OA1. The second common cathode electrode CCE2 may be removed or remain in the opening area OA1.

Referring to FIGS. 7A to 7D, the thin-film encapsulation layer TFE may be located on the light emitting element layer DP-EDL to seal the first and second light emitting elements LD1 and LD2. The thin-film encapsulation layer TFE may cover the active area AA as a whole. The thin-film encapsulation layer TFE may cover a partial area of the peripheral area NAA.

The thin-film encapsulation layer TFE may include a first inorganic layer 71, an organic layer 72, and a second inorganic layer 73 that are stacked in the third direction DR3. In FIGS. 7A-7D, each of the first inorganic layer 71, the organic layer 72, and the second inorganic layer 73 is illustrated as a single layer. However, this is illustrated as an example. For example, at least one of the first inorganic layer 71, the organic layer 72, or the second inorganic layer 73 may be provided in plurality or omitted, and embodiments according to the present disclosure are not limited to any one embodiment.

The first inorganic layer 71 may cover the first and second common cathode electrodes CCE1 and CCE2. The first inorganic layer 71 may prevent or reduce contaminants such as external moisture or oxygen permeating the first and second light emitting elements LD1 and LD2. For example, the first inorganic layer 71 may include a silicon nitride, a silicon oxide, or a compound as a combination thereof. The first inorganic layer 71 may be formed through a deposition process.

The organic layer 72 may be located on the first inorganic layer 71 to be in contact with the first inorganic layer 71. The organic layer 72 may provide a flat surface on the first inorganic layer 71. For example, the organic layer 72 may provide a flat surface.

Unevenness formed on a top surface of the first inorganic layer 71, particles present on the first inorganic layer 71, or the like may be covered by the organic layer 72 to block an effect of a surface state of the top surface of the first inorganic layer 71 on components formed on the organic layer 72. In addition, the organic layer 72 may alleviate stress between layers that are in contact with each other. The organic layer 72 may include an organic matter, and may be formed through a solution process such as spin coating, slit coating, or inkjet process.

The second inorganic layer 73 is located on the organic layer 72 to cover the organic layer 72. The second inorganic layer 73 may be stably formed on a relatively flat surface compared to when being located on the first inorganic layer 71. The second inorganic layer 73 may seal moisture or the like discharged from the organic layer 72 to prevent or reduce the moisture being introduced into the outside. The second inorganic layer 73 may include a silicon nitride, a silicon oxide, or a compound as a combination thereof. The second inorganic layer 73 may be formed through a deposition process.

The display panel 210 may further include first and second dam parts DMP1 and DMP2 located in the peripheral area NAA. As illustrated in FIGS. 7A and 7B, the first and second dam parts DMP1 and DMP2 may have a multilayer structure. The second dam part DMP2 may be located outside the first dam part DMP1. The first dam part DMP1 includes a first lower dam DM1-L, a first intermediate dam DM1-M, and a first upper dam DM1-U. The second dam part DMP2 includes a second lower dam DM2-L, a second intermediate dam DM2-M, and a second upper dam DM2-U.

The first and second lower dams DM1-L and DM2-L may be formed simultaneously with the fifth insulation layer 50. The first and second intermediate dams DM1-M and DM2-M are provided on the first and second lower dams DM1-L and DM2-L, respectively. The first and second intermediate dams DM1-M and DM2-M may be formed simultaneously with the sixth insulation layer 60. The first and second upper dams DM1-U and DM2-U are provided on the first and second intermediate dams DM1-M and DM2-M, respectively.

The first and second dam parts DMP1 and DMP2 may be provided to the peripheral area NAA in a closed loop shape so as to surround the active area AA. Thus, the first and second dam parts DMP1 and DMP2 prevent or reduce liquid organic matters being spread to the outside during the forming of the organic layer 72 of the thin-film encapsulation layer TFE. The organic layer 72 may be formed by coating the liquid organic matters on the first inorganic layer 71 by using an inkjet method. Here, the first and second dam parts DMP1 and DMP2 may set a boundary of an area in which the liquid organic matters are located.

According to some embodiments of the present disclosure, the first dam part DMP1 may partially overlap the first source power line EVLS1. FIGS. 7A and 7B illustrate a structure in which the two parts DMP1 and DMP2 are provided, but embodiments according to the present disclosure are not limited thereto. That is, the display panel 210 may be provided only one of the first and second dam parts DMP1 and DMP2. In addition, FIGS. 7A and 7B illustrate a structure in which the first and second dam parts DMP1 and DMP2 are spaced apart from each other, but embodiments according to the present disclosure are not limited thereto. For example, the first and second dam parts DMP1 and DMP2 may be connected to each other. In addition, a structure in which each of the first and second dam parts DMP1 and DMP2 has a triple-film structure is illustrated, but each of the first and second dam parts DMP1 and DMP2 may have a double-layer structure.

FIGS. 6 to 7D illustrate a structure in which the first and second source power lines EVSL1 and EVSL2 do not overlap each other on a plane (or in a plan view). That is, the first and second source power lines EVSL1 and EVSL2 are located on the same layer, and arranged to be spaced apart from each other on a plane (or in a plan view). However, embodiments according to the present disclosure are not limited thereto. That is, the first and second source power lines EVSL1 and EVSL2 may be located on the different layers from each other, and arranged to overlap each other on a plane (or in a plan view).

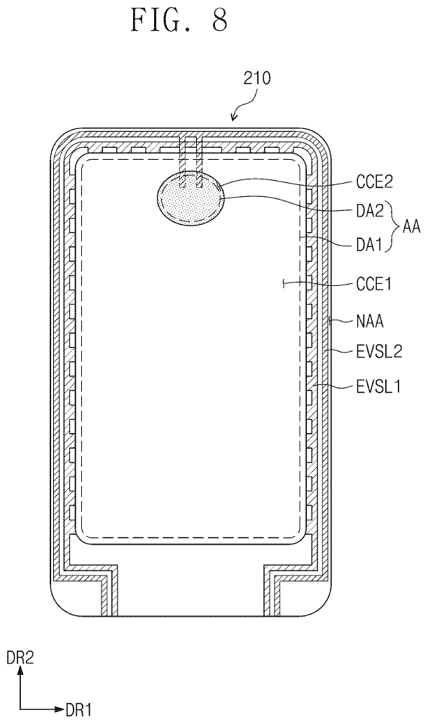

FIG. 8 is a plan view of a display panel according to some embodiments of the present disclosure. For example, FIG. 8 is a plan view illustrating a line layout of a display panel according to some embodiments different from the embodiments illustrated and described with respect to FIG. 6. In the description with reference to FIG. 8, the components described with reference to FIGS. 6 to 7D are designated by the similar reference symbols, and descriptions thereof are omitted.

Referring to FIG. 8, an active area AA of a display panel 210 includes first and second display areas DA1 and DA2. A first common cathode electrode CCE1 is located in the first display area DA1, and a second common cathode electrode CCE2 is located in the second display area DA2. The first and second cathode electrodes CCE1 and CCE2 may be arranged to be spaced apart and electrically insulated from each other.

The first common cathode electrode CCE1 may be defined as an electrode that is provided by connecting, in common, the first cathode electrodes of the first light emitting elements LD1 provided in the first pixels PX1 illustrated in FIGS. 3A and 5A. That is, the first cathode electrodes of the first light emitting elements LD1 may be provided as one body to be provided in the form of a single-body electrode like the first common cathode electrode CCE2.

The second common cathode electrode CCE2 may be defined as an electrode that is provided by connecting, in common, the second cathode electrodes of the second light emitting elements LD2 provided in the second pixels PX2 illustrated in FIGS. 3A and 5A. That is, the second cathode electrodes of the second light emitting elements LD2 may be provided as one body to be provided in the form of a single-body electrode like the second common cathode electrode CCE2.

A first source power line EVSL1 electrically connected to the first common cathode electrode CCE1, and a second source power voltage ELVSS2 electrically connected to the second common cathode electrode CCE2 are located in the peripheral area NAA. The first and second source power lines EVSL1 and EVSL2 may be arranged so as to surround three sides of the active area AA. Pads extending from both ends of each of the first and second source power lines EVSL1 and EVSL2 may be located in the peripheral area NAA on which the pads PD (illustrated in FIG. 1B) of the display panel 210 are located.

The first source power line EVSL1 may be located inside the second source power line EVSL2. The first source power line EVSL1 is electrically connected to the first common cathode electrode CCE1, and the second source power line EVSL2 is electrically connected to the second common cathode electrode CCE2.

The display panel 210 according to some embodiments as illustrated in FIG. 8 may include the second display area DA2 having a circular shape on a plane (or in a plan view) unlike the display panel 210 (see FIG. 6) according to some embodiments as illustrated in FIG. 6. The second display area DA2 may be surrounded by the first display area DA1.

The first common cathode electrode CCE1 may overlap the first display area DA1 and the second display area DA2. The second common cathode electrode CCE2 may overlap the second display area DA2. In addition, the second common cathode electrode CCE2 may overlap the first display area DA1.

FIG. 9A is an enlarged plan view of a portion of a display panel according to some embodiments of the present disclosure. FIGS. 9B and 9C are enlarged cross-sectional views of a portion of a display panel according to some embodiments of the present disclosure. For example, FIG. 9A is a schematic plan view illustrating some of lines overlapping a first display area and a second display area according to some embodiments of the present disclosure. FIG. 9B is a cross-sectional view taken along the line IV-IV′ illustrated in FIG. 9A. FIG. 9C is a cross-sectional view of a display panel according to some embodiments different from the embodiments illustrated and described with respect to FIG. 9B.

Referring to FIGS. 9A and 9B, the display panel 210 (see FIG. 6) according to some embodiments may include a first power part and a second power part.

The first power part may supply a first power voltage to a first common cathode electrode CCE1. The first power part may include a first source power line EVSL1 and a first power auxiliary line SEVSL1. The first source power line EVSL1 may be located in the peripheral area NAA (see FIG. 6). The first power auxiliary line SEVSL1 may be branched from the first source power line EVSL1. The first power auxiliary line SEVSL1 may extend to the first display area in the peripheral area NAA (see FIG. 6). The first power auxiliary line SEVSL1 may be electrically connected to the first common cathode electrode CCE1.

The second power part may supply a second power voltage to a second common cathode electrode CCE2. According to some embodiments, the second power voltage may have a higher voltage level than the first power voltage.

The second power part may include a second source power line EVSL2 and a second power auxiliary line SEVSL2. The second source power line EVSL2 may be located in the peripheral area NAA (see FIG. 6). The second power auxiliary line SEVSL2 may be branched from the second source power line EVSL2. The second power auxiliary line SEVSL2 may extend to the first display area and the second display area in the peripheral area NAA (see FIG. 6). The second power auxiliary line SEVSL2 may be electrically connected to a second cathode.

A first pixel group PG1 may be located in the first display area DA1. The first pixel group PG1 may be provided in plurality. The first pixel group PG1 may be electrically connected to the first power auxiliary line SEVSL1 in the first display area DA1. As illustrated in the drawing, the first pixel groups PG1 may overlap the first power auxiliary line SEVSL1.

A second pixel group PG2 may be located in the second display area DA2. The second pixel group PG2 may be provided in plurality. The second pixel group PG2 may be electrically connected to the second power auxiliary line SEVSL2 in the second display area DA2. As illustrated in the drawing, the second pixel groups PG2 may overlap the second power auxiliary line SEVSL2.

As illustrated in the drawing, the first power auxiliary line SEVSL1 and the second power auxiliary line SEVSL2 may be provided to have a mesh pattern. However, embodiments according to the present disclosure are not limited thereto. For example, only one power auxiliary line may be provided to have a mesh pattern, and embodiments according to the present disclosure are not limited to any one embodiment.

A dummy pixel group PG2_DM may be located in the second display area DA2. The dummy pixel group PG2_DM may include a plurality of dummy pixels. The dummy pixel group PG2_DM may be provided in plurality. The dummy pixel group PG2_DM may not be electrically connected to the transistor unlike the second pixel group PG2, but is not limited thereto. For example, the dummy pixel group PG2_DM may also be electrically connected to the transistor like the second pixel group PG2, and embodiments according to the present disclosure are not limited to any one embodiment.

The first common cathode electrode CCE1 may overlap the first display area DA1 and the second display area DA2. The first common cathode electrode CCE1 may overlap the first pixel groups PG1 and the second pixel groups PG2.

The second common cathode electrode CCE2 may overlap the second display area DA2. The second common cathode electrode CCE2 may overlap the second pixel groups PG2 and the dummy pixel group PG2_DM. The second common cathode electrode CCE2 may be spaced apart from the first display area DA1. However, embodiments according to the present disclosure are not limited thereto. For example, the second common cathode electrode CCE2 may overlap also a portion of the first display area DA1, and embodiments according to the present disclosure are not limited to any one embodiment.

A hole HH may be located in the second display area DA2. The hole HH may be located in the dummy pixel group PG2_DM. The hole HH may overlap a dummy pixel of the dummy pixel group PG2_DM on a plane (or in a plan view). However, embodiments according to the present disclosure are not limited thereto. For example, the hole HH may be located in an area, which does not overlap a second pixel and the dummy pixel, of the second display area DA2, and embodiments according to the present disclosure are not limited to any one embodiment.

As the hole HH is located in the area that does not overlap the dummy pixel or the second pixel and the dummy pixel, an empty area of the display areas DA1 and DA2 may be utilized. Accordingly, an integration level of components in the display panel 210 (see FIG. 6) may be increased, and the display panel 210 (see FIG. 6) may be capable of having a ultrasmall size.

The hole HH may be provided in plurality. According to some embodiments, at least some of the holes HH may overlap the second power auxiliary line SEVSL2 on a plane (or in a plan view).

Some of the holes HH may be located in an edge of the first display area DA1 on a plane (or in a plan view). That is, some holes HH may be arranged to be adjacent to the first display area DA1. Alternatively, the holes HH may be arranged along an edge of the second display area DA2.

Referring to FIG. 9B, the first power auxiliary line SEVSL1 and the second power auxiliary line SEVSL2 may be located on the fifth insulation layer 50. The first common cathode electrode CCE1 may be located on the sixth insulation layer 60. A portion of the first common cathode electrode CCE1 may pass through the sixth insulation layer 60 to be electrically connected to the first power auxiliary line SEVSL1.

A cathode insulation layer CCE-IL may be located on the sixth insulation layer 60. The cathode insulation layer CCE-IL may be located on the first common cathode electrode CCE1. The second common cathode electrode CCE2 may be located on the cathode insulation layer CCE-IL.

A first inorganic layer 71 of the thin-film encapsulation layer TFE (see FIG. 7A) may be located on the second common cathode electrode CCE2.

The first power auxiliary line SEVSL1 may be located on the same layer as the first anode AE1 (see FIG. 7A). The second power auxiliary line SEVSL2 may be located on the same layer as the second anode AE2 (see FIG. 7C).

However, embodiments according to the present disclosure are not limited thereto. For example, the second power auxiliary line SEVSL1 and the second power auxiliary line SEVSL2 may be different layers from each other, and embodiments according to the present disclosure are not limited to any one embodiment.

The hole HH may pass through the cathode insulation layer CCE-IL, the first common cathode electrode CCE1, and the sixth insulation layer 60. A portion of the second common cathode electrode CCE2 may be connected to a second power part through the hole HH. The portion of the second common cathode electrode CCE2 may be electrically connected to the second power auxiliary line SEVSL2 to be connected to the second power part.

Here, the cathode insulation layer CCE-IL, the first common cathode electrode CCE1, and the sixth insulation layer 60 may be removed by a laser drilling method, and embodiments according to the present disclosure are not limited thereto.

Referring to FIG. 9C, a second common cathode electrode CCE2 according to some embodiments of the present disclosure may overlap a first display area DA1. Even though the second common cathode electrode CCE2 overlaps the first display area DA1, a cathode insulation layer CCE-IL may be located between a first common cathode electrode CCE1 and the second common cathode electrode CCE2 so that the first common cathode electrode CCE1 and the second common cathode electrode CCE2 are electrically insulated from each other.

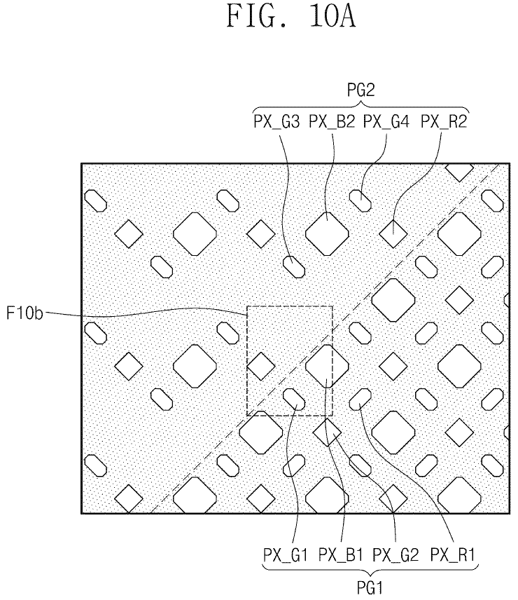

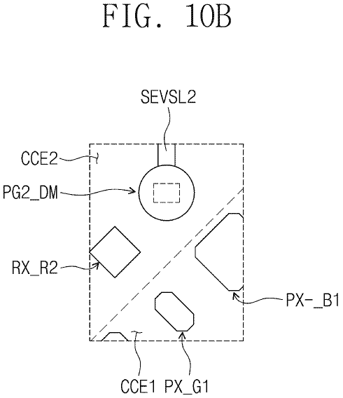

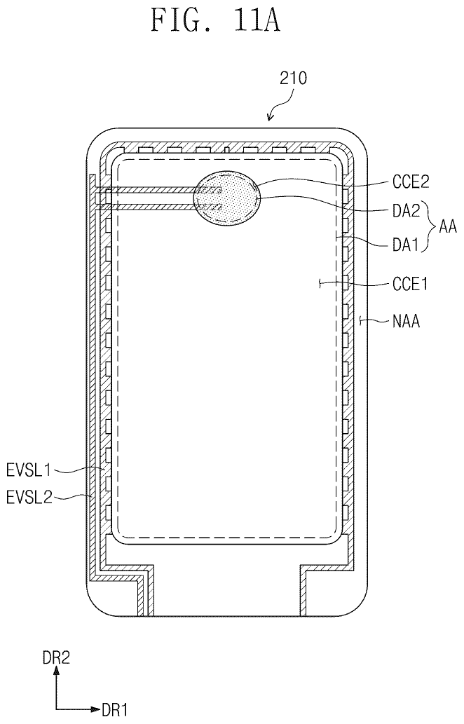

FIGS. 10A and 10B are enlarged plan views of a portion of the display panel 210 (see FIG. 6) according to some embodiments of the present disclosure. For example, FIG. 10A is a plan view illustrating pixels of a first area and a second area according to some embodiments of the present disclosure. FIG. 10B is an enlarged view of an area F10b in FIG. 10A.

Referring to FIGS. 10A and 10B, the display panel 210 (see FIG. 6) according to some embodiments of the present disclosure may include a first pixel group PG1 including a first green pixel PX_G1, a first blue pixel PX_B1, and a first red pixel PX_R1 that are arranged in one direction in the first display area DA1 (see FIG. 9A). The display panel 210 may include a second pixel group PG2 including a second green pixel PX_G2, a second blue pixel PX_B2, and a second red pixel PX_R2 that are arranged in one direction in the second display area DA2 (see FIG. 9A).

Here, as illustrated in the drawing, an area occupied by one first pixel group PG1 relative to an entire surface area of the first display area DA1 (see FIG. 9A) may be smaller than an area occupied by one second pixel group PG2 relative to an entire surface area of the second display area DA2 (see FIG. 9A). However, embodiments according to the present disclosure are not limited thereto. For example, the areas occupied by the first pixel group PG1 and the second pixel group PG2, respectively, may be the same, and embodiments according to the present disclosure are not limited to any one embodiment. However, also in this case, the second display area DA2 may be greater than the first display area DA1 in terms of the luminance per unit pixel.

Referring to FIG. 10B, a dummy pixel group PG2_DM may be spaced apart from the second red pixel PX_R2. However, embodiments according to the present disclosure are not limited thereto. For example, a dummy pixel of the dummy pixel group PG2_DM may be spaced apart from the second blue pixel PX_B2 or the second green pixel PX_G2, and embodiments according to the present disclosure are not limited to any one embodiment.

FIG. 10B illustrates the dummy pixel group PG2_DM being present in the second display area DA2 (see FIG. 9A), but embodiments according to the present disclosure are not limited thereto. For example, the dummy pixel group PG2_DM may not be present, and embodiments according to the present disclosure are not limited to any one embodiment.

The second power auxiliary line SEVSL2 may overlap the dummy pixel on a plane (or in a plan view). According to some embodiments, the second power auxiliary line SEVSL2 may be spaced apart from the first red pixel PX_R1 or the first blue pixel PX_B1 on a plane (or in a plan view), but embodiments according to the present disclosure are not limited thereto. For example, the second power auxiliary line SEVSL2 may overlap the first red pixel PX_R1 or the first blue pixel PX_B1 on a plane (or in a plan view), and embodiments according to the present disclosure are not limited to any one embodiment.

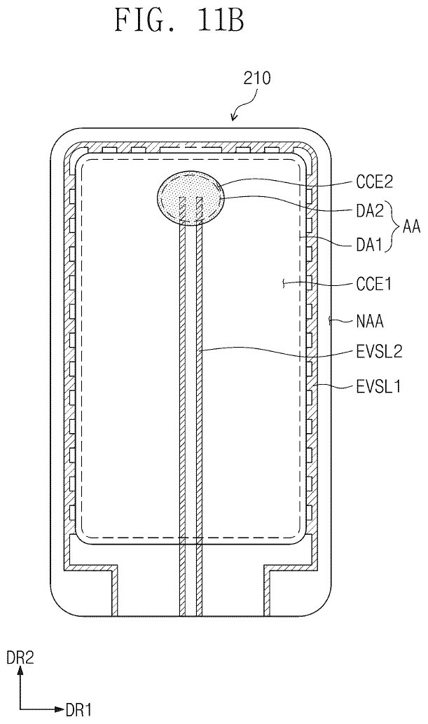

FIGS. 11A and 11B are plan views of a display panel according to some embodiments of the present disclosure. For example, FIGS. 11A and 11B are plan views illustrating a line layout of a display panel according to some embodiments different from the embodiments of the inventive concept illustrated in FIGS. 6 and 8, respectively. In the description with reference to FIGS. 11A and 11B, the components described with reference to FIGS. 6 and 8 are designated by the similar reference symbols, and descriptions thereof are omitted.

Referring to FIG. 11A, the first source power line EVSL1 may be arranged so as to surround three sides of the active area AA. The second source power line EVSL2 may be arranged so as to surround some sides of the active area AA. The second source power line EVSL2 may be arranged to be adjacent to one side of the active area AA.

As one example, the second source power line EVSL2 may be arranged to be adjacent to a side positioned at a side portion of the active area AA. The second source power line EVSL2 may extend in the first direction DR1 to overlap the first display area DA1 and the second display area DA2.

However, embodiments according to the present disclosure are not limited thereto. For example, the second source power line EVSL2 may be arranged so as to surround two sides of the active area AA, and embodiments according to the present disclosure are not limited to any one embodiment.

The second power auxiliary line BE2 (see FIG. 7C) may be branched from one position of the second source power line EVSL2 so as to have a minimum distance from the second source power line EVSL2 to the second display area DA2. In addition, the second power auxiliary line BE2 (see FIG. 9A) may extend in a direction in which the second power auxiliary line BE2 has the minimum distance to the second display area DA2.

Referring to FIG. 11B, a first source power line EVSL1 may be arranged so as to surround three sides of an active area AA. A second source power line EVSL2 may be arranged so as to surround some sides of the active area AA. The second source power line EVSL2 may be arranged to be adjacent to a side, which is not surrounded by the first source power line EVSL1, of sides of the active area AA.

As one example, the second source power line EVSL2 may be arranged to be adjacent to a side positioned at a lower portion of the active area AA. The second source power line EVSL2 may extend in the second direction DR2 to overlap the first display area DA1 and the second display area DA2.

In the display panel according to some embodiments and the display device including the display panel, the levels of the power voltages supplied to the first pixel and the second pixel may be different from each other to relatively improve the sharpness difference between the first display area and the second display area. Under the same input signal, the luminance of the light output from the second light emitting element may be higher than the luminance of the light output from the first light emitting element. Accordingly, the sharpness difference between the first and second display areas may be relatively improved, and the overall display quality may be relatively improved.

In the display panel according to some embodiments and the display device including the display panel, the voltage lines that supply the power voltages to the first pixel and the second pixel, respectively, may be separated from the cathodes of the first pixel and the second pixel to provide the voltage levels of the voltages supplied to the pixels, respectively, to be different from each other. Accordingly, the voltages having the voltage levels required for the pixels may be adjusted and supplied, and the power consumption may be relatively reduced.

Although the embodiments of the present invention have been described, it is understood that the present invention should not be limited to these embodiments but various changes and modifications can be made by one ordinary skilled in the art within the spirit and scope of the present invention as hereinafter claimed. Therefore, the technical scope of the inventive concept is not limited to the contents described in the detailed description of the specification, but should be determined by the claims, and their equivalents.

What is claimed is:

1. A display panel comprising:
a display area comprising a first area having a first light transmittance, and a second area adjacent to the first area and having a second light transmittance higher than the first light transmittance;
a plurality of first pixels, each of which is configured to provide the first area with light and comprises a first cathode;
a plurality of second pixels, each of which is configured to provide the second area with light, and comprises a second cathode overlapping the first cathode in a plan view and electrically insulated from the first cathode;
a first power part connected to the first cathode and configured to supply a first power voltage to the first cathode;
a second power part connected to the second cathode and configured to supply a second power voltage different from the first power voltage to the second cathode; and
a cathode insulation layer between the first cathode and the second cathode.

2. The display panel of claim 1, wherein a hole passing through the first cathode and the cathode insulation layer is defined in the second area, and
the second cathode passes through the first cathode and the cathode insulation layer through the hole to be connected to the second power part.

3. The display panel of claim 2, wherein the hole is in an edge of the first area.

4. The display panel of claim 2, further comprising a dummy pixel in the second area,
wherein the hole overlaps the dummy pixel in the plan view.

5. The display panel of claim 2, wherein the hole is provided in plurality,
wherein the holes are arranged along an edge of the second area.

6. The display panel of claim 1, wherein the second cathode is spaced apart from the first area in the plan view.

7. The display panel of claim 1, wherein the second cathode overlaps the first area and the second area in the plan view.

8. The display panel of claim 1, wherein the second power voltage has a lower voltage level than the first power voltage.

9. The display panel of claim 2, wherein:
the first power part comprises:
a first power line in a peripheral area adjacent to the display area; and
a first power auxiliary line branched from the first power line, and extending from the peripheral area to the first area to be electrically connected to the first cathode, and
the second power part comprises:
a second power line in the peripheral area; and
a second power auxiliary line branched from the second power line, and extending from the peripheral area to the second area to be electrically connected to the second cathode.

10. The display panel of claim 9, wherein the hole and the second power auxiliary line overlap each other in the plan view.

11. The display panel of claim 9, wherein the second power auxiliary line extends along the first area so as to have a minimum distance between the second area and the peripheral area.

12. The display panel of claim 9, further comprising:
a base layer on which the first power line and the second power line are located; and
a first insulation layer on the base layer,
wherein the first cathode is on the first insulation layer.

13. The display panel of claim 12, further comprising:
a first anode on the base layer and overlapping the first area;
a second anode on the base layer and overlapping the second area; and
an organic layer on the base layer and comprising an emission layer,
wherein the second power auxiliary line is on a same layer as the second anode.

14. A display panel comprising:
a display area including a first area having a first light transmittance, and a second area adjacent to the first area and having a second light transmittance higher than the first light transmittance;
a first anode in the first area;
a second anode in the second area;
an organic layer comprising an emission layer on the first anode and the second anode;
a first cathode on the first area;
a second cathode in the second area, on a different layer from the first cathode, and electrically insulated from the first cathode;
a first power part connected to the first cathode; and
a second power part connected to the second cathode,
wherein a hole defined in the second area and passing through the first cathode is defined,
wherein the second cathode passes through the first cathode through the hole to be connected to the second power part.

15. The display panel of claim 14, further comprising a cathode insulation layer between the first cathode and the second cathode,
wherein the hole further passes through the cathode insulation layer, and
the second cathode passes through the first cathode and the cathode insulation layer through the hole to be connected to the second power part.

16. The display panel of claim 15, further comprising a peripheral area adjacent to the display area,
wherein the first power part comprises:
a first power line in the peripheral area; and
a first power auxiliary line branched from the first power line, and extending from the peripheral area to the first area to be electrically connected to the first cathode, and
wherein the second power part comprises:
a second power line in the peripheral area; and
a second power auxiliary line branched from the second power line, and extending from the peripheral area to the second area to be electrically connected to the second cathode.

17. The display panel of claim 16, wherein the hole and the second power auxiliary line overlap each other in a plan view.

18. The display panel of claim 16, further comprising:
a base layer on which the first power line and the second power line are located; and
a first insulation layer on the base layer,
wherein the first cathode is on the first insulation layer.

19. The display panel of claim 18, wherein the first anode and the second anode are on the base layer, and
the second power auxiliary line is on a same layer as the second anode.

20. The display panel of claim 15, wherein the first power part is configured to supply a first power voltage to the first cathode, and
the second power part supplies a second power voltage having a lower voltage level than the first power voltage to the second cathode.
